(19) United States
(12) Patent Application Publication
(10) Pub. No.: US 2026/0313779 A1
(43) Pub. Date: Oct. 8, 2026

(54) NANOSECOND PULSING ELECTRIC FIELD GENERATED MICROPLASMAS

(71) Applicant: NEW YORK UNIVERSITY, New York, NY (US)

(72) Inventors: Ryan L. HARTMAN, New York, NY (US); Jasmine C. SABIO, Huntsville, AL (US); Yukun LIU, San Diego, CA (US)

(73) Assignee: NEW YORK UNIVERSITY, New York, NY (US)

(21) Appl. No.: 19/483,508

(22) PCT Filed: May 13, 2024
(86) PCT No.: PCT/US2024/029147

§ 371 Date: Nov. 11, 2025

Related U.S. Application Data
(60) Provisional application No. 63/466,101, filed on May 12, 2023.

(51) Int. Cl. H05H 1/24; H01J 37/32

(52) U.S. Cl. CPC H05H 1/247; H01J 37/32449; H01J 37/32568

(57) ABSTRACT

Methods for producing plasma reactors are provided. Plasma reactors may include microfluidic channels to control flows of liquids and gases within a reaction volume. Electrodes provide an electrical field across at least a portion of the reaction volume, generating a plasma within the reactor. The plasma may be controlled through adjustment of the input to the electrodes. A method of using a plasma reactor to generate reactions between chemical reactants in a liquid phase and the plasma phase is also provided. Catalysts may be used to increase selectivity and efficiency of the reactions.

### CROSS-REFERENCE TO RELATED APPLICATIONS

This application claims priority to and the benefit of U.S. Provisional Patent App. No. 63/466,101, filed May 12, 2023, the content of which is incorporated by reference in its entirety.

### STATEMENT OF GOVERNMENT INTEREST

This invention was made with government support under Grant No. CBET-2032664, Grant No. CBET-1551116, and Grant No. CBET-2231429, awarded to the National Science Foundation Grants. The government has certain rights in the invention.

### TECHNICAL FIELD

The present disclosure relates generally to nanosecond pulsing electric field-generated microplasmas.

### BACKGROUND

Since the industrial revolution, the heart of the chemical processes driving the chemical industry has relied on the combustion of fossil fuels. Although some incremental reductions in greenhouse gas emissions have occurred, the full adoption of zero-carbon renewable energy sources to drive the chemical industry has remained an elusive goal. The world cannot wait for this industry to evolve in this direction naturally. To trigger this transformation, the fundamental scientific and technological gaps that stand in the way of the electrification of the chemical industry must be addressed.

Further, the vast majority of chemical feedstocks are petroleum-based. Methane, the largest component of natural gas, is an abundant feedstock that often goes to waste or is, regrettably, released to the atmosphere. Often produced in remote locations its onsite valorization is attractive for commercial applications, though conversions of less than 30% are the state-of-the-art and require energy intensive catalytic processes to form light alkanes and other useful organic compounds. Downstream in fine chemicals and pharmaceuticals, methylations of small molecule organics are attractive due to their enhanced solubility in therapeutics. However, such reactions typically require the use of organomethane sources with multiple synthetic reactions and separations steps to generate the products, and so are difficult to perform at the production site.

Plasma reactors present a relatively unexplored method of facilitating chemical reactions that otherwise may be unachievable and may provide chemical synthesis pathways that are not dependent on combustion processes. Plasma reactors are able to ionize reactants, opening up reaction pathways that may otherwise be unavailable. However, traditional thermal plasmas present a harsh environment for reactants and catalysts. The high temperatures and high levels of ionization may interfere with the desired chemical synthesis or may destroy delicate reactants or catalysts before they are able to produce the desired products. Selectivity and efficiency may also be negatively impacted. The use of methane plasma, where the C—H bonds are activated to react with other reagents, can generate entirely new chemical process routes to useful fine chemicals and pharmaceutical intermediates using renewable electricity.

### SUMMARY

Atmospheric pressure, low temperature plasmas (LTPs) have emerged as a strategic environment for many chemical reactions, including those utilizing reactants and/or catalysts that cannot be used in traditional thermal plasmas, such as the direct methylation of organometallic compounds. Different from traditional thermal plasmas, in LTPs molecules may be ionized to form a mixture of charged and neutral species at relatively low temperatures and with low degrees of ionization (10⁻⁴ to 10%). Plasma reactor technology has achieved success in initiating organic reactions, whose selectivity usually requires mild conditions. Motivated by advances in heterogeneous catalysts, such as nanoparticles, zeolites and metals, current efforts in this field primarily rely on the intrinsic reactivity of plasmas to activate an acceptor molecule. Breakthroughs in the field of chemical conversion could be obtained by combining chemical activation via formation of atmospheric plasmas with transition metal catalysis.

In a first aspect, a method of producing a chemical product is provided. The method includes providing a first plasma reactor that itself includes a reaction volume in liquid communication with a first inlet, a second inlet, and an outlet, the reaction volume including reaction channels to direct the flow of liquids within the first plasma reactor; a first electrode positioned adjacent at least a portion of a first side of the reaction volume; and a second electrode position adjacent at least a portion of the second side of the reaction volume. An electrical field generator is electrically connected to the first electrode of the first plasma reactor and to the second electrode of the plasma reactor. The electrical field generator is operable to generate an electric field across at least a portion of the reaction volume of the first plasma reactor. A first stream containing a first chemical reactant in a gaseous state is fed into the first plasma reactor through the first inlet into the reaction volume such that at least a portion of the first stream contacts at least one of the first electrode and the second electrode and generates a non-thermal plasma within the reaction volume of the first plasma reactor. A second stream containing a second chemical reactant in a liquid state is fed into the reaction volume through the second inlet. The method also includes controlling the properties of the non-thermal plasma through adjustment of the waveform, pulse rate, amplitude, voltage, or other properties of the electrical field generated by the electrical field generator. A product stream containing the chemical product is collected from the outlet of the first plasma reactor.

The reactor designs provided herein may include a counter-current, packed-bed dielectric barrier discharge in a microreactor, which has several advantages. The design allows for high-energy density electric fields on-chip, which are more difficult to establish in larger scale systems. Thus, the present design allows for more precise control of the plasma characteristics, including its reactive composition. The method also makes possible multiphase reactions with organometallic complexes at methane plasma-liquid interfaces. Plasma-liquid interfaces are often unstable. Methane plasma reaction chemistry is incredibly complex and difficult to study experimentally, as the reactions are often mass transfer limited and the experiments expensive and time consuming. The current invention creates the possibility of studying multiphase, plasma “flash” chemistry, or reactions that occur on very fast time scales, and in a continuous-flow reactor. The reactor designs provide a new and more accurate method for the study and measurement of methane plasma reaction kinetics. The designs could be used for predictive modeling in manufacturing scale-ups, to high-throughput screen catalysts/intermediates, optimize multivariate conditions, to map the reaction space topology for chemical manufacturing purposes, or to manufacture compounds such as organometallic complexes often produced as high value small quantity products.

In an embodiment the reaction channels are microfluidic channels, millifluidic channels, or combinations thereof. In an exemplary embodiment, the reaction channels are shaped to establish multifluidic flow of the first chemical reactant and the second chemical reactant. In an embodiment, the product stream collected at the outlet of the first plasma reactor is a gaseous product or a liquid product. In an exemplary embodiment, the first chemical reactant is a hydrocarbon. In an exemplary embodiment, the first chemical reactant is a C1-C5 hydrocarbon, such as methane, ethane, n-propane, isopropane, n-butane, isobutane, pentane, n-pentane, isopentane, or cyclopentane. In an exemplary embodiment, the second chemical reactant is an aryl heteroatom; an aryl amine, a di-aryl compound, an alkane, an alkene, an aryl, or an amine, polymers, an organometallic complex, a fine chemical, or a pharmaceutical precursor. In an exemplary embodiment, the second stream also contains a catalyst and may include an organometallic catalyst. In some embodiments, the catalyst includes a transition metal complex. In some embodiments, the catalyst includes at least one of cobalt, nickel, palladium, copper, nickel, platinum, titanium, titanium dioxide, rubidium, rhodium, or iridium.

In an embodiment, the method includes applying a machine learning module to data collected during operation of the first plasma reactor and changing at least one of the flow rate of the first stream, the flow rate of the second stream, the first chemical reactant, the second chemical reactant, the catalyst in the second stream, and the waveform, pulse rate, amplitude, or voltage provided by the electrical field generator based on the machine learning module.

In an embodiment, the method includes passing the collected product stream through a second plasma reactor. In an exemplary embodiment, the method includes feeding the collected product stream into a second inlet of a second plasma reactor, wherein the second plasma reactor includes: a second reactor reaction volume in liquid communication with a second reactor first inlet, the second reactor second inlet, and a second reactor outlet, the second reactor reaction volume including second reactor reaction channels to direct the flow of liquids within the second reactor; a second reactor first electrode positioned adjacent at least a portion of a first side of the second reactor reaction volume; and a second reactor second electrode position adjacent at least a portion of a second side of the second reactor reaction volume; providing an electrical field generator electrically connected to the first electrode of the second reactor and to the second electrode of the second plasma reactor, and operating the electrical field generator to generate an electrical field across at least a portion of the reaction volume of the second plasma reactor; feeding a third stream containing a third chemical reactant in a gaseous state through the first inlet of the second plasma reactor into the reaction volume such that at least a portion of the first stream contacts at least one of the first electrode and the second electrode of the second plasma reactor and generates a plasma within the reaction volume of the second plasma reactor; collecting a second product stream containing a second chemical product from the outlet of the second plasma reactor.

In an embodiment, the method includes linking one or more additional plasma reactors in series with the first plasma reactor and with a final plasma reactor, such that at least one of the one or more additional plasma reactors receives as an input at least a portion of the product stream from the first plasma reactor and the final plasma reactor receives as an input at least a portion of a product stream from at least one of the one or more additional plasma reactors.

In an embodiment, the method includes linking one or more additional plasma reactors in parallel with the first plasma reactor. In an exemplary embodiment, the method includes operating one or more additional plasma reactors in parallel with the first plasma reactor and applying a machine learning module to data collected during operation of at least one of the first plasma reactor and the one or more additional plasma reactors, and changing an operating parameter of at least one of the first plasma reactor and the one or more additional plasma reactors based on the machine learning module.

In an embodiment, the reaction channel comprises at least one transparent side. The transparent side may be transparent to one or more of optical light, ultraviolet light, and infrared light. In an exemplary embodiment, the reaction channel comprises an upper wall at least partially formed of a first material and a lower wall at least partially formed a second material. In this exemplary embodiment, the first material may be selected from a metal, a dielectric, a semiconductor, a conductor, or a combination or laminate thereof. In this exemplary embodiment, at least one of the first material and the second material may be at least partially transparent to a target wavelength of electromagnetic radiation, which may facilitate collecting optical, infrared, and/or ultraviolet data through at least one of the first material and the second material.

In a second aspect, a method of hydroalkylation of a chemical reactant is provided. In an exemplary embodiment, the method of hydroalkylation of a chemical reactant includes providing a liquid phase comprising an organometallic catalyst and the chemical reactant; exposing methane to an electric field to generate a low-temperature methane plasma; and interfacing the low-temperature methane plasma with the liquid phase.

In an embodiment, the liquid phase is fed through a reaction channel having microchannels. In an exemplary embodiment, the methane is fed into the reaction channel having microchannels and the electric field is applied across the microchannels. In an exemplary embodiment, the reaction channel comprises at least one transparent side.

In an embodiment, the reaction channel comprises an upper wall at least partially formed of a first material and a lower wall at least partially formed of a second material. In some embodiments, the first material is selected from a metal, a dielectric, a semiconductor, or a conductor. In some embodiments, at least one of the first material and the second material is at least partially transparent to optical, infrared, or ultraviolet radiation. In some embodiments, the method includes collecting optical or infrared data through at least one of the first material and the second material.

It should be appreciated that all combinations of the foregoing concepts and additional concepts discussed in greater detail below (provided such concepts are not mutually inconsistent) are contemplated as being part of the subject matter disclosed herein. In particular, all combinations of claimed subject matter appearing at the end of this disclosure are contemplated as being part of the subject matter disclosed herein.

### BRIEF DESCRIPTION OF DRAWINGS

The foregoing and other features of the present disclosure will become more fully apparent from the following description and appended claims, taken in conjunction with the accompanying drawings. Understanding that these drawings depict only several implementations in accordance with the disclosure and are therefore, not to be considered limiting of its scope, the disclosure will be described with additional specificity and detail through use of the accompanying drawings.

FIG. 1 shows a schematic of a plasma microreactor according to an exemplary embodiment, with an inset image showing details of the microstructures within the reactor.

FIG. 2A is an image of a top view of a plasma microreactor according to an embodiment, with an inset image showing details of the microstructures within the reactor.

FIG. 2B shows ionization and concentrations of water and peroxide within a plasma microreactor having the microstructures according to an embodiment.

FIG. 3 is a schematic of a microreactor design featuring longitudinal channels having square ends.

FIG. 4A is a schematic of a microreactor design featuring longitudinal channels having rounded ends and featuring horizontal slits.

FIG. 4B is a schematic of a microreactor design featuring longitudinal channels having rounded ends and featuring horizontal slits.

FIG. 5 is a schematic of a microreactor design channels in a rounded configuration.

FIG. 6 is a drawing of a side view of a plasma microreactor showing various layers of the microreactors according to an embodiment.

FIG. 7 is an image showing the electrical connections for a plasma microreactor according to an embodiment, with a schematic illustrating the potential of the connections.

FIG. 8 is an image showing waves produced by an electrical field generator.

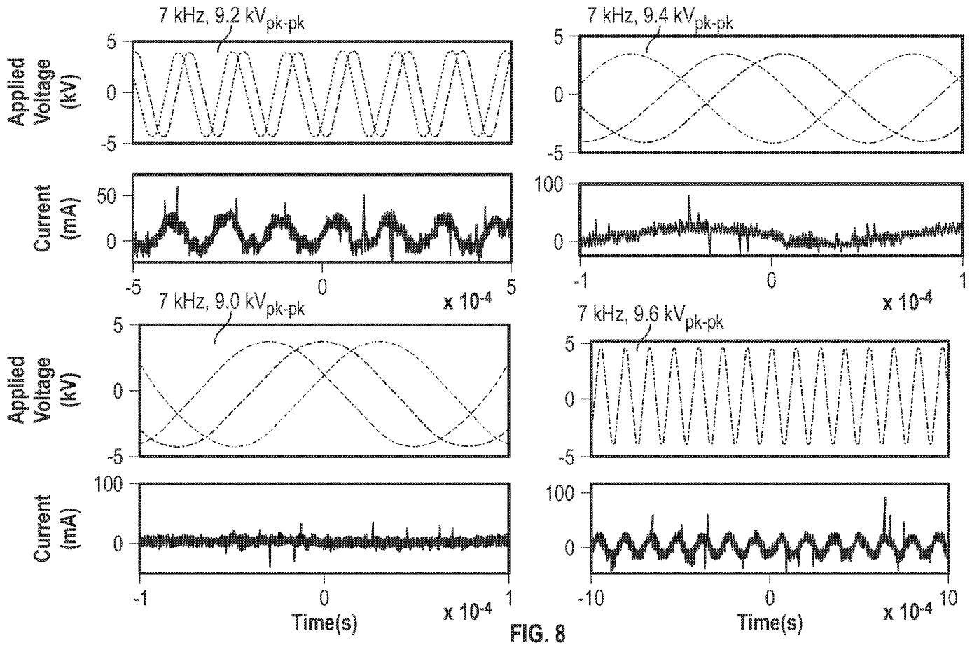

FIG. 9 is a schematic of a method of operating a plasma microreactor, according to an embodiment.

FIG. 10 is a schematic of a method of hydroalkylating a chemical reactant using a plasma microreactor, according to an embodiment.

FIG. 11 is a schematic of a plasma microreactor system having a controller, sensors, and an AI unit, according to an embodiment.

FIG. 12 is a schematic illustrating the use of a neural network and machine learning algorithms.

FIG. 13 is a plot of temperature within the reaction zone of a plasma microreactor as measured by an infrared measuring tool, the temperature shown related to the voltage applied to the microreactor for five different mixtures of argon and methane from an experiment according to an embodiment.

FIG. 14 is spectroscopy results of gas in the reaction zone of a plasma microreactor from an experiment according to an embodiment.

FIG. 15A is plot showing annular and slug flow regimes in a plasma microreactor from an experiment according to an embodiment.

FIG. 15B is an image showing annular flow regimes in a plasma microreactor from an experiment according to an embodiment.

FIG. 15C is an image showing slug flow regimes in a plasma microreactor from an experiment according to an embodiment.

FIG. 16A are plots showing UV absorption as a function of time collected during an experiment according to an embodiment.

FIG. 16B are plots showing UV absorption as a function of time collected during an experiment according to an embodiment.

FIG. 17 is a schematic of the formation of a C—H bond and formation of an oxygen bond, with a plot showing conversion and selectivity as a function of residence time.

FIG. 18 is a plot showing conversion and selectivity as a function of residence time as measured in experiments performed according to an embodiment.

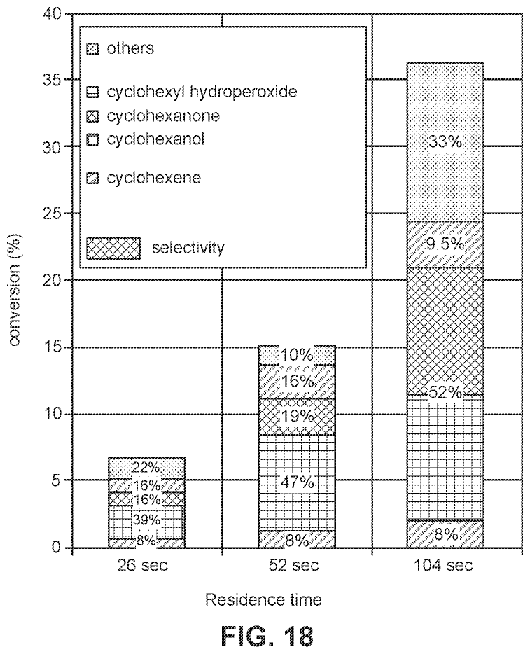

FIG. 19 is a schematic of methylation reactions of various species.

FIG. 20 is a schematic of a methylation reaction of 1,4-dibromobenzene.

FIG. 21 is a schematic showing the methylation of an organometallic catalyst precursor.

FIG. 22 is a schematic showing catalytic cycles for cross-coupling of methane plasma to bromobenzene.

FIG. 23 is a plot Raman spectroscopy results of products from an experiment according to an embodiment.

FIG. 24 is a schematic of a computer system according to an embodiment.

Reference is made to the accompanying drawings throughout the following detailed description. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

### DETAILED DESCRIPTION

Embodiments described herein relate generally to the use of a multiphase plasma reactor to carry out chemical reactions between reactants in the plasma phase and reactants in a second phase to overcome transport and mass transfer limitations. Multi-phase plasma-catalytic micro-reactors are presented that are able to intensify processes where transport limitations exist, increasing reactivity, efficiency, and selectivity.

### Multi-Phase Plasma Microreactor Design

A multi-phase plasma-catalytic microreactor is provided. Low temperature plasmas (LTPs) may be controlled very precisely using electric and magnetic fields. The reactor designs presented in this disclosure leverage microfluidic fabrication techniques to generate low temperature, atmospheric plasmas with controllable properties, and to control and optimize the interface and available surface area between plasma-based reactants and catalysts and reactants within a liquid phase. The plasmas may be produced by Dielectric Barrier Discharge (DBD) techniques as known in the art. In a DBD plasma, a high voltage is applied to a pair of parallel electrodes separated by a dielectric barrier. The dielectric barrier helps to confine the plasma discharge to a narrow gap between the electrodes, which reduces the power required to maintain the plasma.

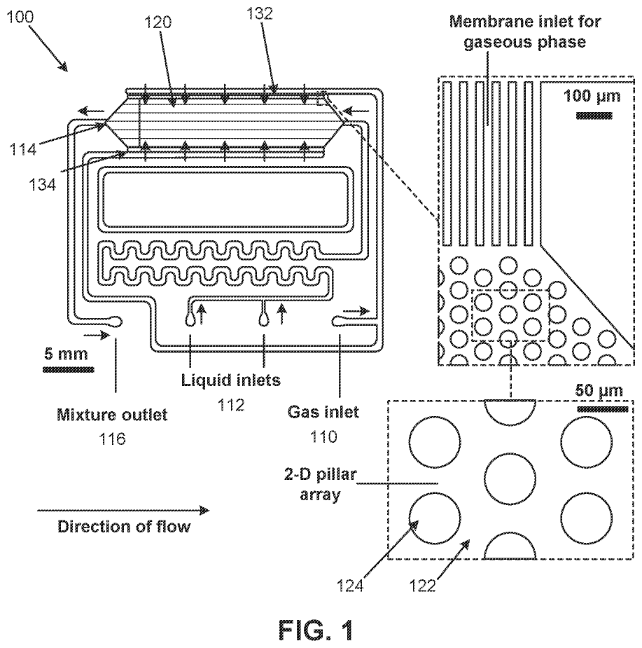

With reference to FIG. 1, the multi-phase plasma-catalytic microreactor (100) may include a reaction chamber (120) having a plurality of inlets (110, 112) for receiving reactants and at least one outlet for collection of products (114). The reaction chamber (120) provides the physical volume for interfacing the reactants and any catalyst such that the reactions are able to occur. The reaction chamber (120) is not constrained to any particular shape, but should be able to accommodate sufficient volume for the desired reactions to take place. The liquid inlets (112) are configured to receive a liquid containing a reactant and to direct the liquid to the reaction chamber (120). The plasma microreactor may include any number of liquid inlets as needed to provide the desired mass or molar rate of reactant to the reaction chamber (120). For example, FIG. 1 shows two liquid inlets (112), but additional liquid inlets are also contemplated. Use of a single liquid inlet (112) is also contemplated. In some embodiments, the reaction chamber (120) has an elongated or square shape such that it can be considered to include one or more ends and one or more sides. In some embodiment, the liquid phase enters the reaction chamber at or near an end of the reaction chamber (120).

One or more gas inlets (110) are configured to receive a gas-phase reactant and to direct the gas stream to the reaction chamber (120). In some embodiments, one or more gas inlets (110) are arranged axially along a length of the reaction chamber (120) such that the gas enters the reaction chamber from the sides of the reaction chamber. In other embodiments, the gas enters the reaction chamber at or near the same end as the liquid phase enters the reaction chamber (120). In yet other embodiments, the gas enters the reaction chamber (120) at or near the end opposite the end where the liquid phase enters. The side entry or opposite end entry configurations are preferred, as it provides cross- and counter-flow interactions between the gas and liquid phases. The side entry configuration has the additional advantage of directing the gas to pass over the electrodes (described below). In some embodiments, the outlet (114) is configured to receive the mixed liquid/gas products. In some embodiments, separate gas and liquid outlets are provided to receive gas products and liquid products, respectively. In embodiments with less than 100% conversion, some amount of gas and/or liquid reactants would also be expected to be collected at the one or more outlets (114).

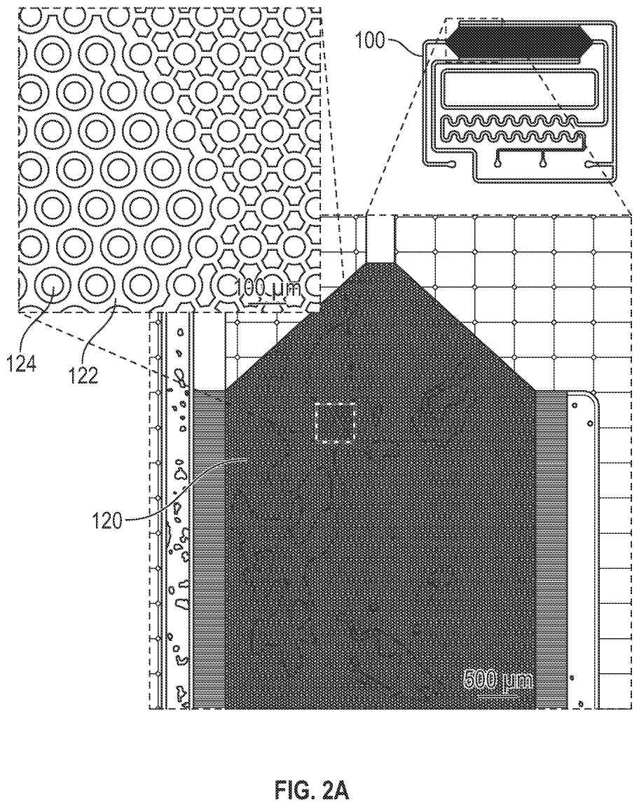

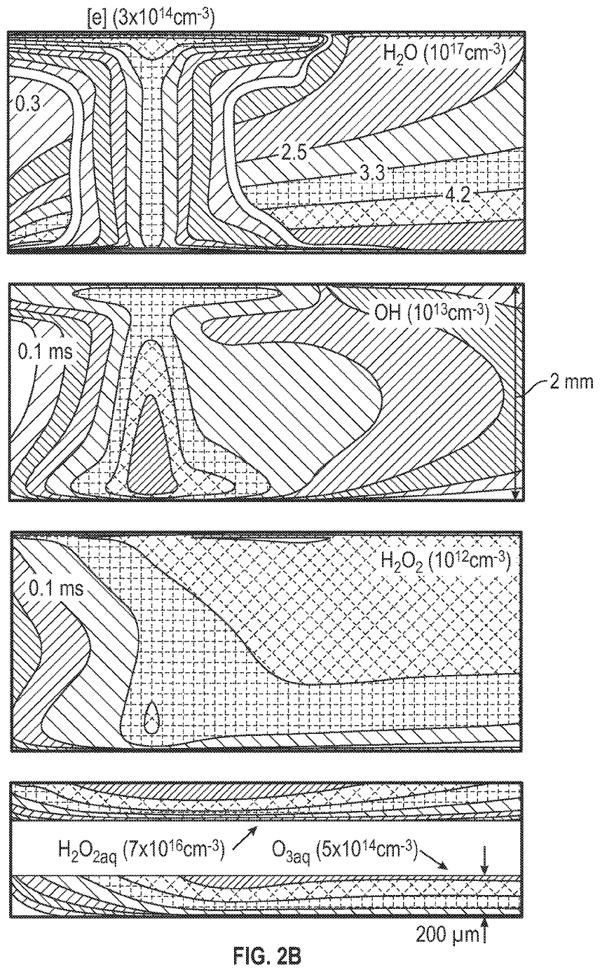

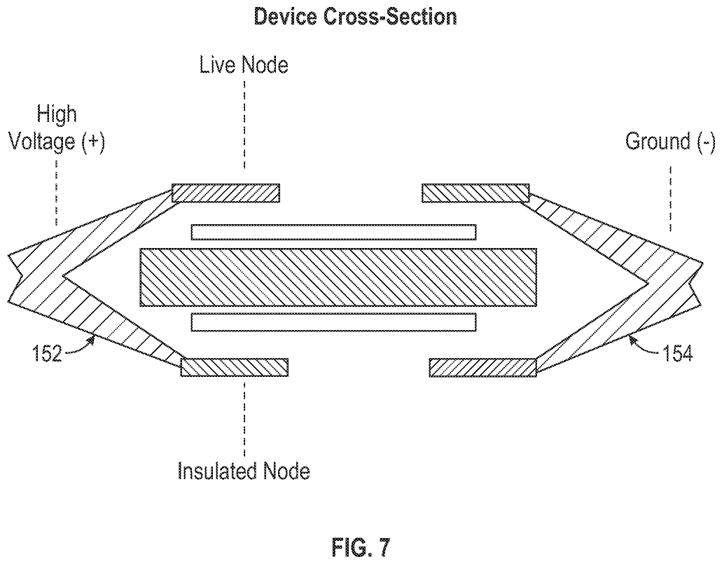

With reference to FIGS. 1 and 2, a first electrode (132) and a second electrode (134) are positioned along the sides of the reaction chamber (120). The electrodes (132, 134) may be formed of a single material, or may be a composite. The electrodes (132, 134) may be formed of the same material, or may be made of different materials. In some embodiments, the first electrode (132) is formed of copper. In some embodiments, the second electrode (134) is formed of chromium. The electrodes (132, 134) are in electrical communication with a power source through an electric field generator. The electric field generator is capable of controlling the supply of electrical current to the first and second electrodes 132, 134 as illustrated in FIG. 7A. The reactor electrodes (132, 134) may be connected to the electrical field generator by wiring, such as an electrode clamp. A high voltage clamp provides electrical current and voltage to one of the electrodes (132) while a ground clamp provides a ground to the other clamp (134). The electric field generator may provide a constant current to the electrodes, or may provide current in a wave, as illustrated in FIG. 7(B). The wave provided by the electric field generator may be sinusoidal, square, triangular, or of any other commonly used wave form. The electrodes create an electric field across at least a portion of the reaction chamber (120). The electrical field generator is capable of controlling other aspects of the current provided to the electrodes, such as the amperage and the frequency and amplitude of the wave produced. In some embodiments, the electrical field generator provides electrical current to the electrodes at a frequency of from 1 kHz to about 100 kHz. In other embodiments, the electrical field generator provides electrical current to the electrodes at a frequency of about 100 kHz to about 1 MHz. The electrical field generator may pulse the electricity provided to the electrodes (132, 134). The pulses may have a fixed frequency or a variable frequency. In some embodiments, the frequency of the pulses is between about 1 kHz to about 100 kHz. In some embodiments, the frequency of the pulses is between about 100 kHz to about 1 MHz (i.e., microseconds). In some embodiments, the frequency of the pulses is between about 1 MHz to about 1 GHZ (i.e., nanoseconds). In some embodiments, the pulse frequency is constant. In other embodiments, the pulse frequency is varied over time.

During operation of the reactor, a first reactant may be fed into a first inlet (110). The first reactant is typically in the gas phase. The first reactant passes into the electric field generated by the electrodes (132, 134) in the reaction chamber (120). Once exposed to the electric field within the reaction chamber (120), the first reactant will become ionized and will become a plasma. The amount of ionization may be adjusted by adjusting the voltage and/or the frequency provided by the electric field generator. For example, higher voltages across the electrodes (132, 134) will result in high levels of ionization within the plasma.

During operation of the reactor, a second reactant is fed into a second inlet (112). Additional inlets may be available for feeding of additional reactants into the reaction chamber. The second reactant is typically in a liquid phase or may be fed in a liquid carrier. The second reactant passes into the reaction chamber (120) where it is exposed to the plasma comprising the first reactant. The plasma and liquid will form a plasma/liquid interface. Control of the plasma/liquid interface is critical to controlling the rate and selectivity of the reactions.

With continued reference to FIGS. 1 and 2, in some embodiments, the reaction chamber (120) may include millifluidic or microfluidic channels (122). Millifluidic channels are understood to be channels that have a characteristic length scale that is on the scale of about 1 to hundreds of millimeters. Microfluidic channels are understood to be channels having a characteristic length scale that is on the scale of about 1 micron to hundreds of microns. Smaller nanoscale channels, having a characteristic length scale on the order of tens to hundreds of nanometers may also be useful to include in the reaction chamber. It is also contemplated that a reaction chamber (120) may feature a combination of liquid channels, some that are on the millifluidic channels and others that are microfluidic channels, and optionally channels that are nanoscale. For simplicity, the channels are described hereafter as being microfluidic channels. However, it should be understood that the term microfluidic channel could also encompasses millifluidic or nanoscale liquid channels or combinations of microfluidic, millifluidic, and/or nanoscale channels. The microfluidic channels (122) may be formed by walls, pillars, or other structures (124) within the reaction chamber (120). In some embodiments, the microfluidic channels create conditions similar to packed bed for the liquid flowing through the reaction chamber (120).

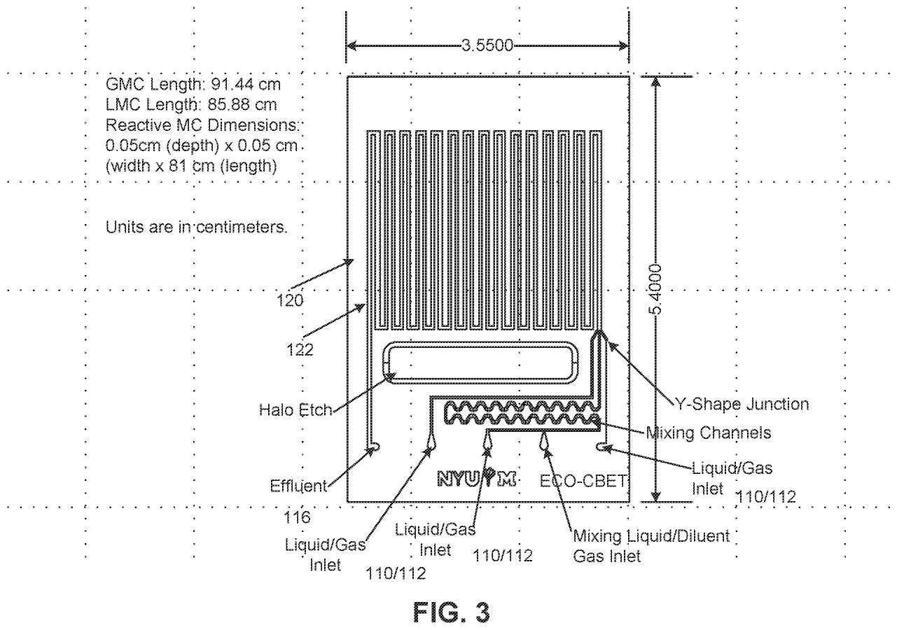

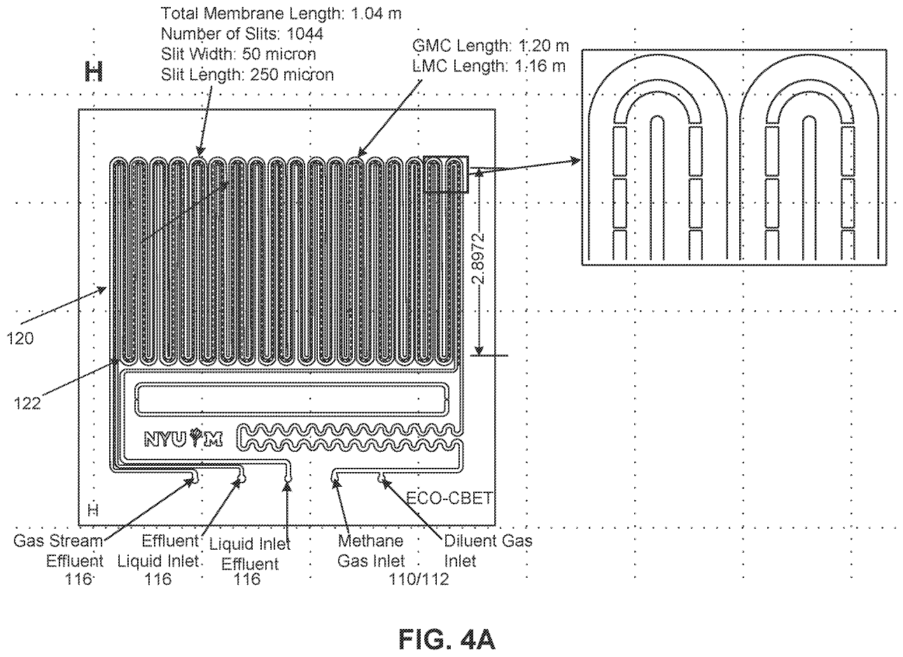

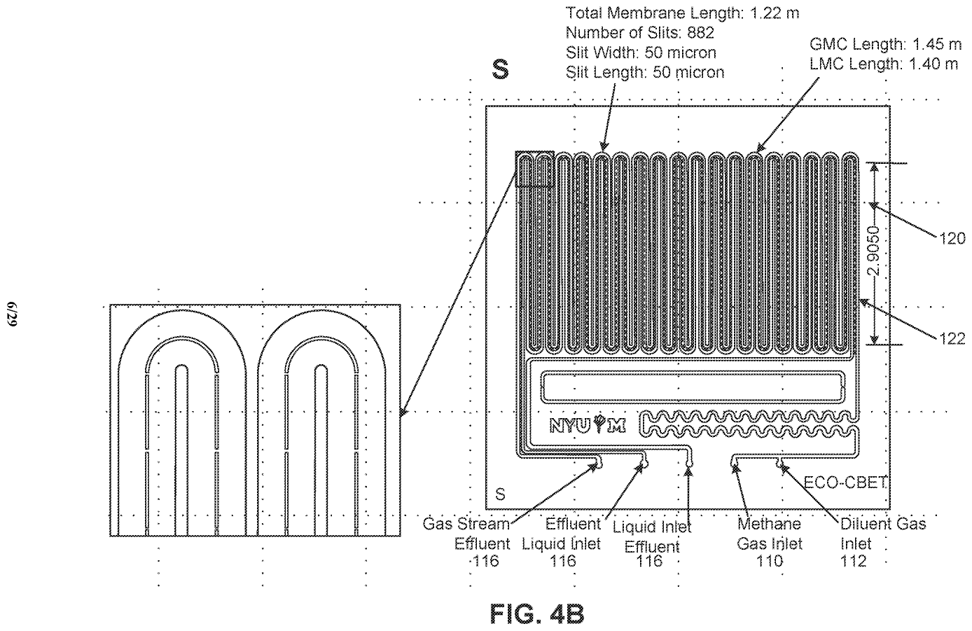

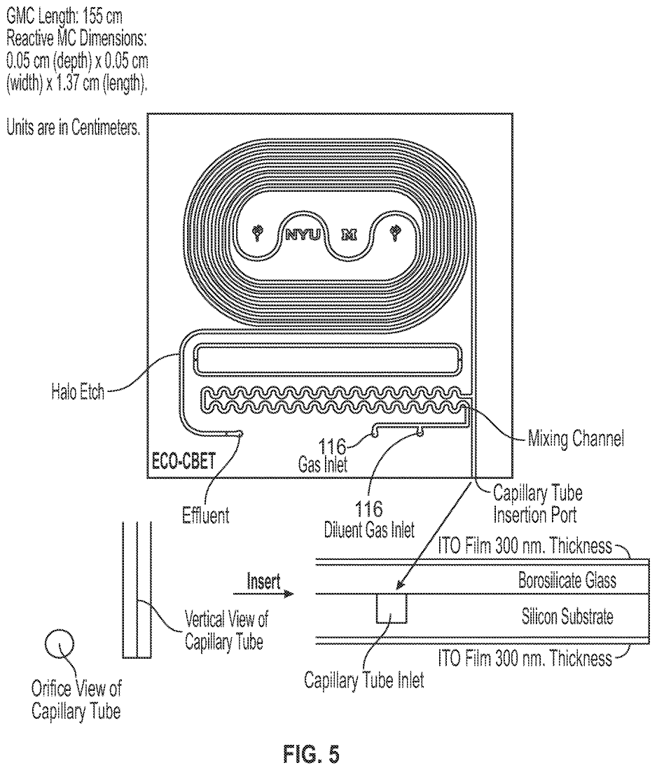

The microfluidic channels (122) are designed to institute multiphase flow within the reaction chamber (120) with cross and counterflow patterns within the microfluidic channels. The low Reynold's number of the liquids flows in the channels cause the liquid flows to be very laminar and structured. The microfluidic channels (122) are designed to provide relatively large reaction volumes and to facilitate contact of the ionized reactants in the plasma phase with the reactants contained within the liquid phase. Several designs for the microfluidic channels are provided herein, but it should be understood that other designs are possible. For example, FIG. 2 shows microfluidic channels (122) formed by columns (124) within a reaction chamber (120). FIGS. 3-5 show alternative microfluidic channel configurations. FIG. 3 shows a configuration with parallel microfluidic channels arranged longitudinally, each channel connected to another channel at an end using a square or sharp connection. FIGS. 4A, 4B show microreactors having parallel microfluidic channels arranged longitudinally connected by rounded ends, and including horizontal (4A) or square (4B) slits. FIG. 5 shows a microreactor having a microfluidic channel arranged in a double spiral (or Fermat's spiral) arrangement. Liquid fed into the reactors passes through the microfluidic channels at low Reynold's number flow, typically in creeping flow, and design of the microfluidic channels influences the liquid to have a low thickness. In the liquid flow through the microfluidic channels, due to the small length scales involved, viscous forces dominate over inertial forces, and as a result, the liquid motion is very smooth and predictable. The reactions between the plasma phase reactants and the reactants in the liquid phase are very fast, thus the reactions are mass transfer limited. The largest constraint to the reactions being the transfer of reactants and/or catalyst in the liquid phase to the liquid/plasma interface. The microfluid channels create thin liquid flows, optimizing the surface area of the liquid/plasma interface and reducing the mass transfer limitations of the system.

Mixing of chemical reagents, including any dissolved catalyst or reactants, in the microfluidic channels is sufficiently fast to force any transport limitations to reactive the heterogeneous interfaces, in this case a confined plasma-liquid reactive interface. Well-established dispersion models can also be used to describe reaction and transport within the porous media when liquid-liquid (or gas-liquid) multiphase flows are of interest, as in aqueous-organic reactions.

The plasma microreactor can include one or more sensors configured to detect sensor data regarding the reactions within the reaction chamber (120). The sensor data can include pressure, molecular weight, and temperature. The sensor data can include a temperature of the reaction or a flow rate of the materials within the reaction chamber (120). The sensor data can include dynamic light scattering data detected by a dynamic light scattering (DLS) sensor. The sensor can include nuclear magnetic resonance data detected by a nuclear magnetic resonance (NMR) sensor. The sensor can include high performance liquid chromatography data detected by a chromatography sensor. Other sensors useful in plasma microreactors include mass spectrometry (MS), optical emission spectroscopy (OES), and UV-visible optical absorption spectroscopy (OAS).

The one or more sensors can include an infrared sensor. The infrared sensor can be used to perform infrared photonic readings or infrared themographic readings. The infrared data provided by an infrared sensor may be converted to temperature data. The infrared sensor can detect thermal fluctuations of the reaction, reacting materials, the plasma, the liquid/plasma interface in the reactor, the products formed in the reactor or exiting the reactor, or in the reactor itself. The microreactor system may be paired with IR thermography for temperature, catalytic activity, and exotherm analysis. As described above, IR thermography may be used to determine relative liquid and gaseous feed rates that result in plasma ignition and extinction. A calibrated infrared camera can be contained within an enclosure with the microreactor and can be used to analyze the heat produced in the reaction channel. Data from the camera can be fed to a control system.

The sensors used to measure properties of the microreactor and associated reactions and flowrates are preferably high-speed, high-resolution, and adjustable. In some embodiments, the sensors are able to provide measurements more than once per second, more than 10 times per second, or more than 100 times per second. For example, a suitable OES sensor may have an integration time of are Ims to 10 s with a resolution (determined at full-width at half maximum or FWHM) of 0.06-7.24 nm. An OES sensor may have the capability of measuring light at wavenumbers ranging from 220 nm to 1100 nm, or one or more subsets of this range. Such a device may be useful in fingerprinting reagents, products, and catalysts of interest in the microreactor system. Infrared sensors, such as IR thermography cameras, may be high-resolution (i.e., 640×480 resolution or better) and may have a frame rate of 10 Hz, 20 Hz, or preferably 30 Hz or higher. Connections between sensors and controllers or other devices are preferably high-speed, capable of data transfer rates of 1 Gbps or greater, 10 Gbps or greater, or 100 Gbps or greater.

The ranges disclosed should not be considered strict limitations on the hardware usable in the disclosed apparatuses, systems, and methods. Other ranges are also contemplated including any discreet number contained in the ranges provided. Indeed, in some embodiments, an OES sensor used to capture optical data from the microreactor has an integration time of less than 10 s, less than 1 s, less than 0.1 s, less than 0.01 s, or less than 0.001 s, or any value between 10 s to 0.001 s.

In some embodiments, the one or more sensors measure electrical voltage or current. Sensors may provide electrical signals that may be measured, recorded, and/or visualized using an oscilloscope or similar device. Measuring the electrical voltage or current at different locations of the plasma microreactor provides information on plasma stability and transient events within the plasma microreactor, such as plasma ignition, extinction, or rapid changes in plasma parameters. Oscilloscopes can accurately measure timing parameters, such as the delay between voltage and current waveforms, pulse widths, or the time required for the plasma to reach steady-state conditions. These timing measurements can be crucial for understanding the kinetics of plasma processes and optimizing the reactor's control systems.

In some embodiments, the plasma microreactors disclosed herein may be used to study reaction kinetics. When combined with in situ sensors and analytical methods, multiphase microreaction engineering principles and plasma-liquid modeling, plasma-liquid interfaces can be isolated and studied under exacting conditions. Devices made of semiconductors and/or thin-films of dielectrics (nitrides or oxides) enable isothermal experiments, which lends itself to studying reaction kinetics of low temperature DBD plasmas (LTPs). Temperature gradients may also be intentionally designed and precisely controlled in these microsystems. For instance, a plasma microreactor may be designed and operated to provide for the isolation of reaction exotherms.

Multiple plasma microreactors may be used to create complex molecules, with each reactor handling a specific step or multiple steps in the synthesis of the final product molecule or molecules. Plasma microreactors may be connected in parallel, in series, or with a combination of parallel and series connections. When connected in parallel, multiple reactors may be connected to the same inputs, sharing a source of reactants. Similarly, they may pool products into a single collection. When connected in parallel, individual reactors may have different operating conditions, with variations in temperature, flow rates of reagents, or plasma properties across the reactors. In this way, each reactor can provide data towards optimization of conditions for a particular process or synthesis pathway. Alternatively, each reactor in parallel may operate with the same conditions as another reactor, which is particularly useful when optimal operation conditions have already been identified for a given process.

The plasma microreactors may also operate in series, with the products of a first microreactor providing at least some of the reactants for a subsequent microreactor. The plasma microreactors may receive all of a given reactant from a preceding microreactor. In some embodiments, a first microreactor produces a first gas-phase product, which serves as the gas-phase reagent in a subsequent reactor. Additional reactors may be added to the series. In this way, the reactor series as a whole may perform reactions steps as part of a synthesis process.

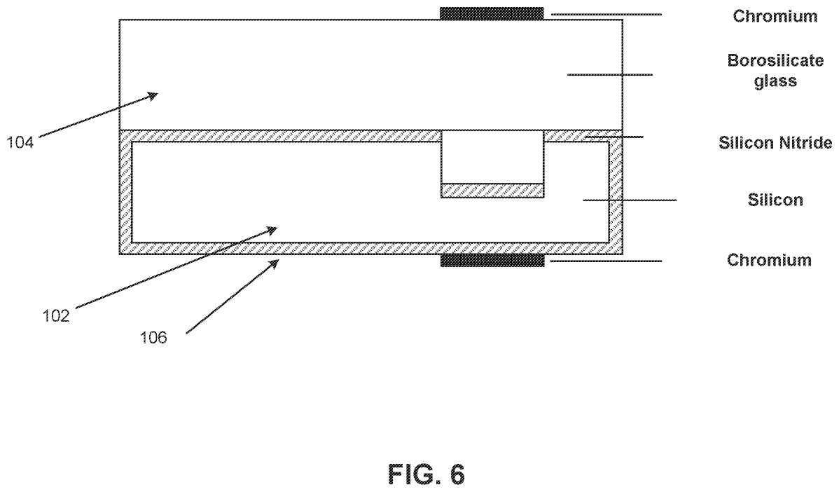

With reference to FIG. 6, a lower portion (102) of the microreactors may be silicon-based, and may be produced using traditional etching, photolithographic, and bonding techniques known in the art to fabricate the physical devices. For example, silicon can be etched using anisotropic deep-reactive ion etching to create devices with the specialized features discussed above. Though silicon is discussed in this disclosure, it should be understood that other dielectric materials, semiconductor materials, or combinations thereof may also be suitable for use in a plasma microreactor. For example, the microreactor may be formed at least partially of glass, plastic, ceramic, or metal oxides. The materials may form at least a portion of the structure of the microreactor (e.g., the reactor top, bottom, or microchannels), or the material may be applied as a coating to specific portions of the microreactor. Silicon is advantageous in that it provides a relatively inert material for containing the low temperature plasmas and manipulation of silicon to produce the fine features of the microreactor are well-practiced in industry. A cover portion (104) encloses the top of the microreactor. The cover portion may be formed of a material that is the same or that is different than the material used for the lower portion. For example, borosilicate may be used, which can provide a translucent boundary for the reactor, allowing for light- or radiation-based measurements to be taken while the reactor is in operation of the microreactor. However, a translucent cover portion (104) is not required by the devices disclosed nor to practice the disclosed methods.

In some embodiments, a dielectric layer (106) is provided on the surface of the lower portion of the microreactor. In some embodiments, the dielectric layer comprises silicon nitride. While not wishing to be bound by a particular theory, it is believed that a layer of dielectric material may, as it becomes polarized, influence the behavior of the plasma within the microreactor. By altering the design elements of the dielectric material, the plasma/liquid interface can be further influenced within the reactor.

### Determination of Plasma Reaction Kinetic Coefficients

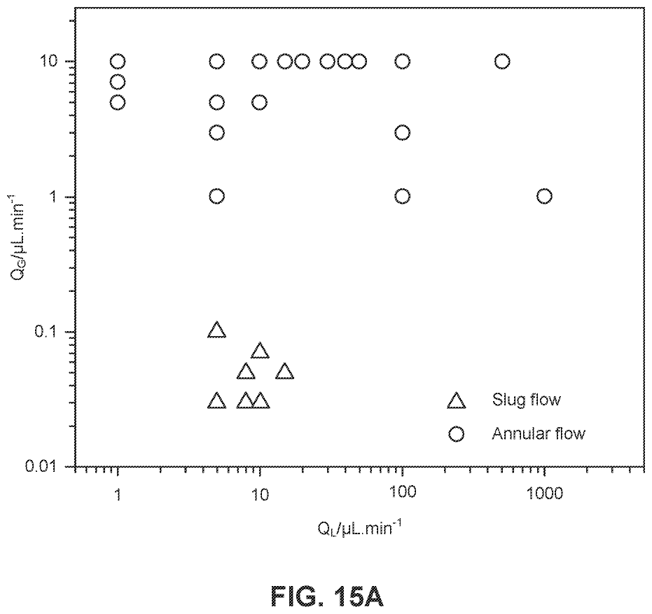

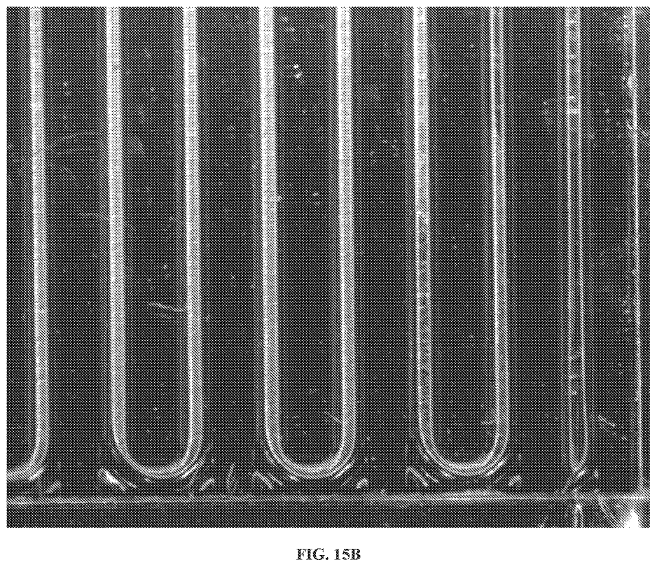

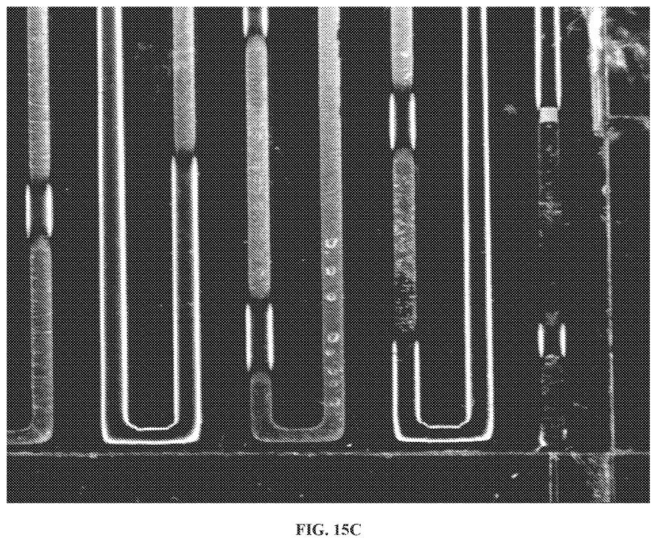

For some microfluid channel designs, fluid flow within the microchannels is observed to fall into either an annular flow regime, with liquid flowing along with sides of the microchannels and gas flowing through the center or annulus, or a slug flow regime with slugs of liquid flowing with gas phase slugs. Such behavior is shown, for example, in FIGS. 15B and 15C. Operation in either flow regime depends on the volumetric flow rate of the gas (Q_{G}) and the volumetric flow rate of the liquid (Q_{L}). The gas and liquid volumentric flow rates may be measured using the same units or different units, for example mL/min or μL/min. The liquid holdup (epsilon) is the volume fraction of the liquid inside the microchannel relative to the plasma and liquid and estimated from their flow rates (Q_{G} and Q_{L}). The epsilon value for a given pair of flow rates can be determined as epsilon=Q_{L}/(Q_{L}+Q_{G}). Estimation of the plasma temperature by infrared (IR) thermography can be used to determine the optimum epsilon values that ignite or extinguish the plasma. Epsilon values can in turn be used to estimate the phase behavior of a plasma-liquid microfluidic flow, and thus correlate the phase behavior regime to the plasma temperature measurements.

Furthermore, epsilon is used to estimate the mass transfer coefficient of chemical reactions that take place at the plasma-liquid interface. In reaction systems that are constrained by mass transfer limitations, the mass transfer coefficient may be used to determine or estimate the chemical reaction coefficients and other variables for the given reaction system. Thus, these measurement techniques enable the prediction of chemical kinetics of plasma-liquid reactions where mass transfer limitations exist. Such data may be analyzed and/or experiments guided by machine learning, as will be explained further below.

### Synthesis Reactions

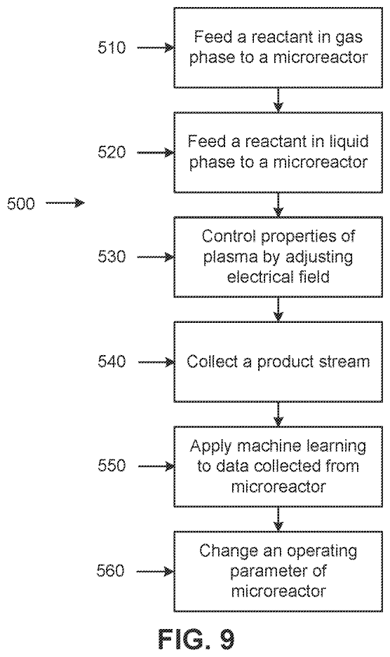

Multi-phase plasma-catalytic micro-reactors may be utilized to perform addition reactions involving methane, ethane, propane, and other alkanes, including direct addition reactions to produce complex chemicals. An embodiment of a method of producing a chemical using a plasma microreactor is illustrated in FIG. 9. At a high level, the method 500 includes feeding a reactant in a gas phase into a microreactor (block 510), feeding a reactant in a liquid phase into a microreactor (block 520), and collecting a product stream from the microreactor (block 540). Optionally, the method 500 may include controlling the properties of the plasma by adjustment of the electrical field (block 530),. The method 500 may also optionally include applying machine learning to data collected from the operation of the microreactor (block 550), and/or changing an operating parameter of the microreactor (block 560).

The desired ligand or addition can be provided in the plasma phase by feeding a suitable feedstock in the gas phase. The desired target molecule for the addition reaction may be fed into the reactor with the liquid phase. Methane provides an ideal feedstock due to the ability of the plasma to generate methyl radicals capable of providing C—H addition reactions. The direct plasma methylation reduces the number of reactions and separations, the amount of chemical waste generated, the carbon footprint of conventional thermochemical routes to arrive at the same compounds, and it could lead to higher methane conversions than the state-of-the-art if methane were recycled to reactors of similar design.

The major chemical products of natural gas are synthesis gas, methanol, hydrocyanic acid, halogenated methanes, and acetylene. Transformations of natural gas to chemicals are primarily based on cracking, a process that heats methane to over a thousand degrees, where C—H bonds in methane cleave and reform into heavier molecules. These high-temperature processes have restricted the utility of natural gas as a chemical feedstock for production of a broader scope of more complex molecules.

The challenge in CH4 augmentation of other molecules is to efficiently activate the inert C—H bond while achieving selectivity by avoiding side-products. The low reactivity of CH4 suggests that energy intensive, forcing conditions are required, but such conditions are usually detrimental to the selectivity. Traditional high-temperature plasma conversion of CH4 suffers from low selectivity over oligomerization of light alkanes, whereas catalytic conversion of CH4 with organometallic catalysis remains impractical due to the low reactivity. Tremendous efforts have been spent on transition metal-catalyzed methane activation for several decades, in which C—H bonds of CH4 are activated under mild conditions with good selectivity. However, low turnover numbers and low turnover frequencies have restricted practical utility of these methods (turnover refers to the frequency with which a single catalyst site produces a product).

The present disclosure provides for novel transformations of CH4 and other alkanes by the use of atmospheric plasma enhancement of liquid-liquid catalysis, which is a vastly unexplored yet potentially highly impactful process. Atmospheric pressure, low temperature plasmas (LTPs) have emerged as a strategic environment to activate alkanes. Different from traditional thermal plasmas, in LTPs plasmas CH4 is ionized to form a mixture of charged and neutral species at low-temperature with low degrees of ionization (10-4 to 10%). Plasma reactor technology has achieved success in initiating organic reactions, whose selectivity usually requires mild conditions. Motivated by advances in heterogeneous catalysts, such as nanoparticles, zeolites and metals, current efforts in this field primarily rely on the intrinsic reactivity of plasmas to activate an acceptor molecule.

High levels of CH4 conversion are obtained by combining CH4 activation via formation of atmospheric plasmas with transition metal catalysis. The present disclosure provides microfluidic fabrication techniques which generate atmospheric plasmas with controllable properties, encourage interaction of the feedstock with organometallic complexes, and provide high levels of catalytic C—C bond formation within the CH4 plasmas. This method allows conversion of CH4 into unique value added chemical products.

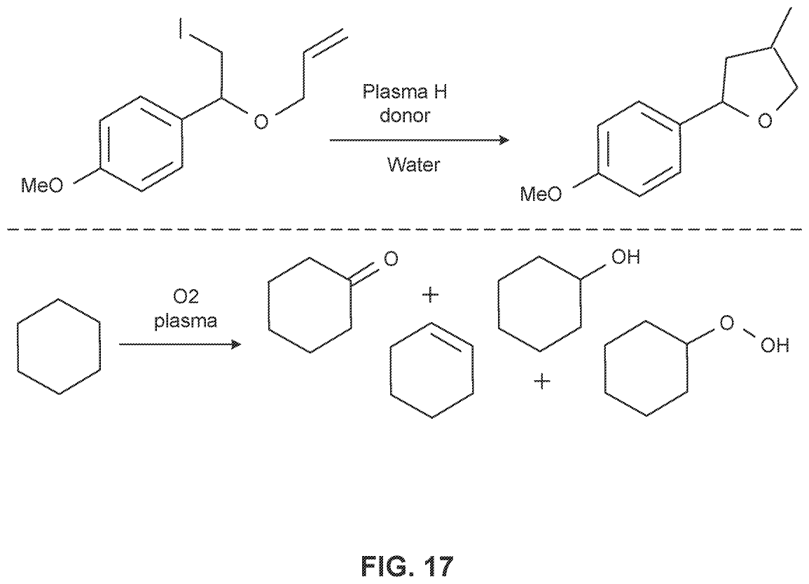

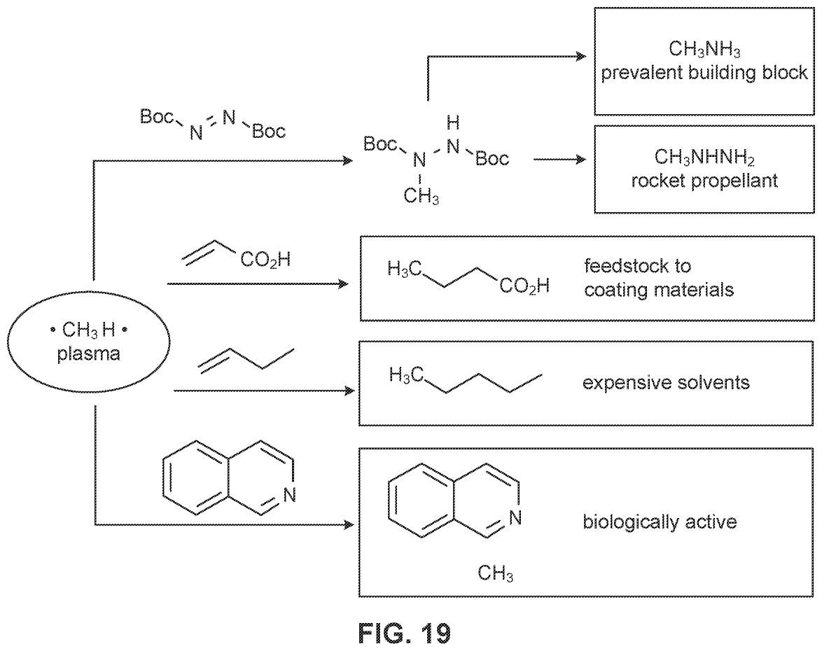

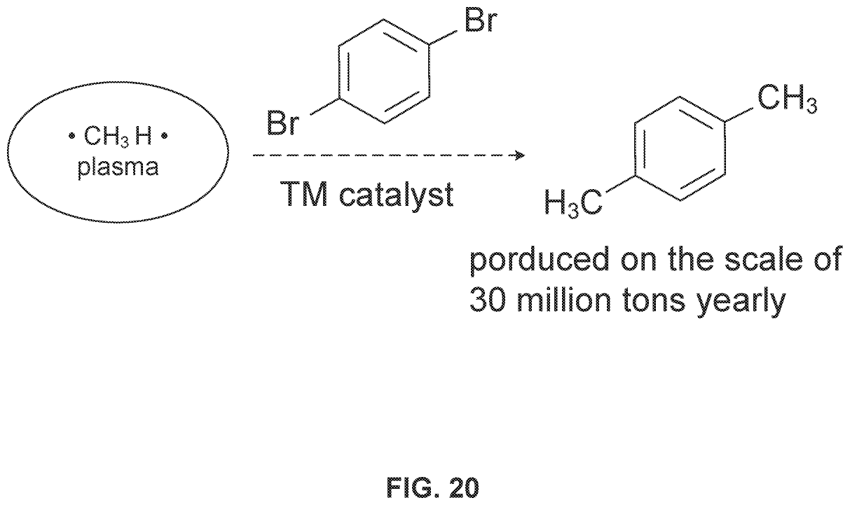

Other bonds are also possible, depending on the reactant provided in the plasma phase. For example, with C—H bonds, C—C, C—O, C—N, N—H, N—O, S—O, S—H, and S—C bonds are also contemplated. The limiting consideration is the reactant, which must be selected to optimize the formation of the desired bond. In some embodiments, methane or another alkane is used to provide ready methylation reactions (see schemes shown in FIGS. 19, 20). In some embodiments, air is used to provide oxygenation reactions. In other embodiments, an aryl is used to provide C—C bonds (see scheme shown in FIG. 17).

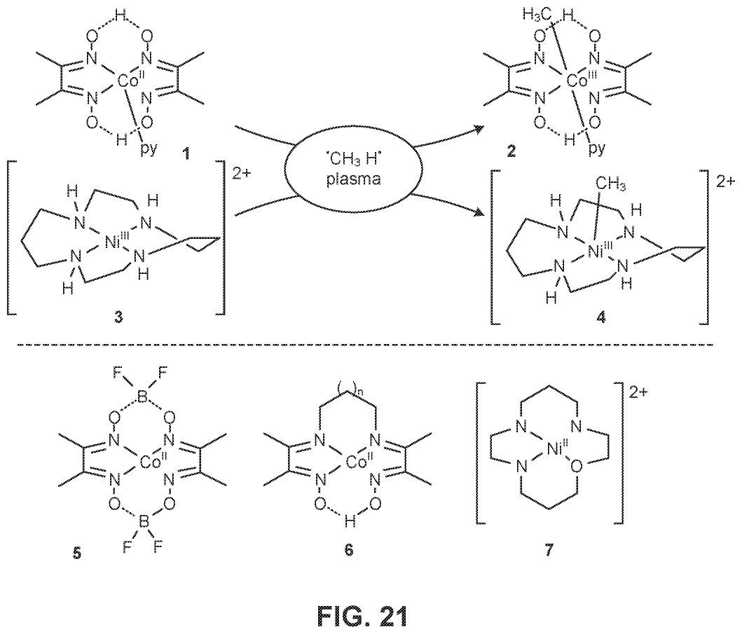

Possible target molecules of the addition reactions include an aryl heteroatom; an aryl amine, a di-aryl compound, an alkane, an alkene, an aryl, or an amine, polymers, an organometallic complex, a fine chemical, or a pharmaceutical precursor. Other addition target molecules are also possible using the plasma microreactor and methods laid out herein. Due to the low temperature and mild reaction conditions, the present method is especially suitable for reactions of delicate chemicals. In some embodiments, the target molecule carried in the liquid phase is an aryl heteroatom. In other embodiments, the target molecule carried in the liquid phase is an aryl amine. In other embodiments, the target molecule carried in the liquid phase is a di-aryl compound. In other embodiments, the target molecule carried in the liquid phase is an alkane. In other embodiments, the target molecule carried in the liquid phase is an alkene. In other embodiments, the target molecule carried in the liquid phase is an aryl. In other embodiments, the target molecule carried in the liquid phase is an amine. In other embodiments, the target molecule carried in the liquid phase is a polymers. In other embodiments, the target molecule carried in the liquid phase is an organometallic complex a catalyst, or catalyst precursor, as illustrated in FIG. 21, for example. In some embodiments, the organometallic complex contains a platinum group metal, copper, cobalt, palladium, or nickel. In other embodiments, the target molecule carried in the liquid phase is a fine chemical or a pharmaceutical precursor.

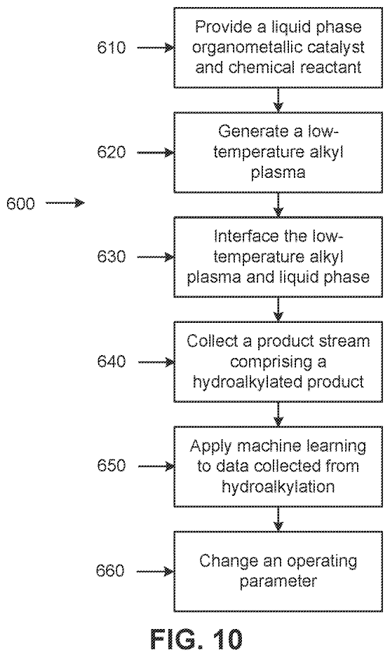

An embodiment of a method of hydroalkylating a reactant using a plasma microreactor is illustrated in FIG. 10. The method 600 includes providing a liquid phase organometallic catalyst and a chemical reactant to a microreactor (block 610), feeding a hydrocarbon to the microreactor and generating an alkyl plasma from the hydrocarbon within by application of an electric field (block 620), and collecting the hydroalkylated product stream from the microreactor (block 640). In some embodiments, the hydrocarbon is methane. Optionally, the method 600 may include interfacing the liquid phase and the alkyl plasma (block 630). The method 600 may also optionally include an optional step (block 650) of applying machine learning to data collected from the operation of the microreactor, and/or changing an operating parameter of the microreactor (block 660).

### Artificial Intelligence and Machine Learning Applications

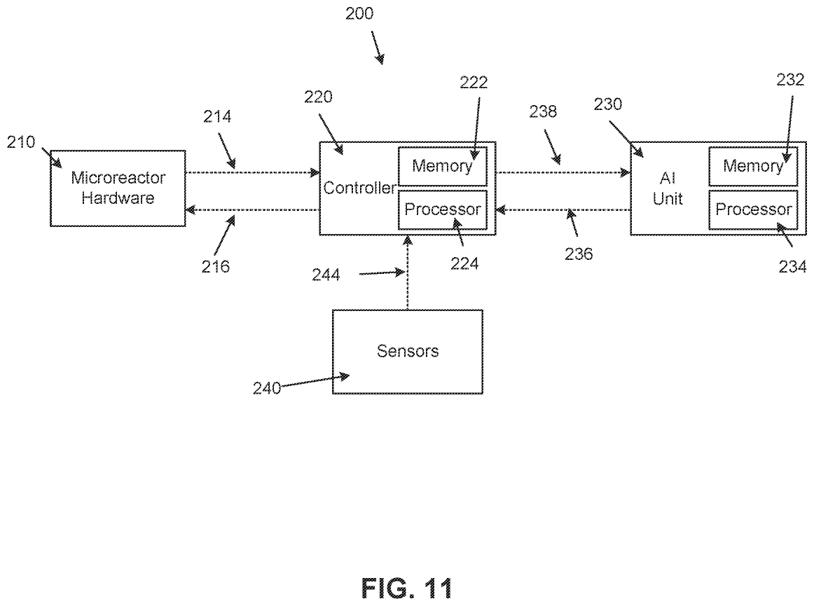

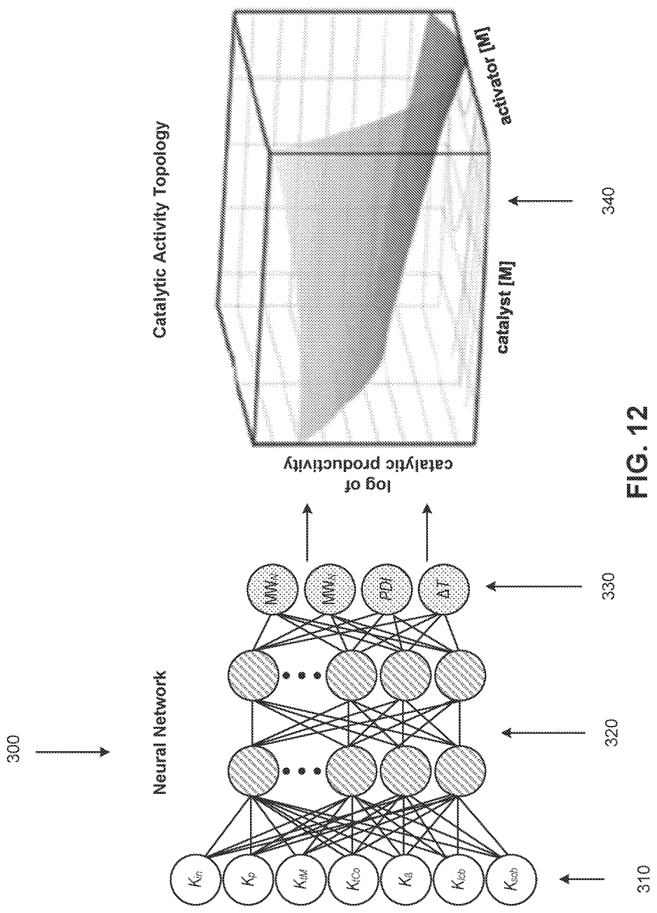

The disclosed plasma microreactors may be used with artificial intelligence (AI) and/or machine learning algorithms to increase experimental efficiency. With reference to FIGS. 11 and 12, the AI can help design experiments by analyzing data and identifying key variables, allowing for the creation of more efficient experimental designs. By using machine learning algorithms to optimize experimental parameters, AI can help reduce the number of experiments required to achieve desired outcomes. AI may also be used to directly or indirectly control variables during experiments. In some embodiments, AI is configured to control experimental variables and analyze the resulting data, thereby running a suite of experiments and exploring the impact of variables on the performance of the microreactor in an autonomous or semi-autonomous fashion.

As illustrated in FIG. 1, in some embodiments, a plasma microreactor is part of a microreactor system 200 controlled by a controller 220 and having microreactor hardware 210, one or more sensors 240, and, optionally, an AI unit 230. The microreactor system 200 may be autonomous, semi-autonomous, or manually controlled.

The microreactor system 200 includes an electronic controller or control unit 220. The controller 220 includes one or more processors 224 and memory 222 for storing computer instructions. The controller 220 may be an electronic controller that operates in a logical fashion to perform operations, execute code configured to provide control algorithms, store and retrieve data, interface with networks, and other desired operations. The controller 220 may include or be configured to access memory, primary storage devices, secondary storage devices, processors, networks, and any other components for executing code. The memory and secondary storage devices may be in the form of read-only memory (ROM) or random access memory (RAM) or integrated circuitry that is accessible by the controller Various other circuits may be associated with the controller 220 such as power supply circuitry, signal conditioning circuitry, control circuitry, driver circuitry, and other types of circuitry.

The controller 220 is configured to provide commands 214 for the microreactor hardware 210 through wired or wireless communications. The controller 220 may control the operation of various aspects of the microreactor system 200 by control of the microreactor hardware, including the feed rates and/or compositions of reactants and catalyst in gas or liquid phases, and the waveform parameters (voltage, frequency, shape) by control of the electrical field generator. The hardware 210 associated with the microreactor may be configured to provide signals 214 to the controller 220 regarding the various operation parameters (i.e., confirmation of instructions, setpoints, etc.).

The controller 220 may be a single controller or may include more than one controller disposed to control various functions and/or features of the microreactor hardware 210. The term “controller” is meant to be used in its broadest sense to include one or more controllers and/or microprocessors that may be associated with the microreactor hardware 210 and that may cooperate in controlling various functions and operations of the machine. The functionality of the controller 220 may be implemented in hardware and/or software without regard to the functionality. The controller 220 may rely on one or more data maps relating to the operating conditions and the operating conditions of the microreactor system 200 that may be stored in the memory associated with the controller. Each of these data maps may include a collection of data in the form of tables, graphs, and/or equations.

In some embodiments, the controller 220 is located near the microreactor 210. In some embodiments, portions of the controller 220 are in a location remote to the microreactor hardware 210, such as at a central server controlling a plurality of microreactors. In such embodiments, the controller 220 may be configured to send and receive signals wirelessly to operate the microreactor system 200. The functionality of the controller 220 may be distributed so that certain functions are performed at or near the microreactor hardware 210 and other functions are performed remotely. In such case, the controller 220 may include a communications system such as wireless communications system for transmitting signals between the microreactor hardware 210, the one or more sensors 240, and the controller 220 or portions of the controller that are located remote from the microreactor hardware. In an embodiment, a remote control unit positioned remote from the microreactor hardware 210 may provide some or all of the specific commands that are then transmitted by the wireless communications system to portions of the microreactor system. In embodiment in which portions of the microreactor system are remote from one another, due to the high volume of data produced, high speed data connections are preferred, such as wired communication connections capable of handling high rates of data transfer. In some such embodiments, the data connection is capable of transferring data at rate that is 1 Gbps or greater, 10 Gbps or greater, or 100 Gbps or greater. Such connections may be wireless, or may include physical connections including but not limited to copper wiring, CAT5e ethernet or other suitable ethernet cable, and/or fiber optic cables.

The controller 220 is configured to interface with one or more sensors 240 and to receive data 240 from the one or more sensors. The sensors may provide data on feed rates of reactants and/or catalysts, flow rates of gas and liquid product streams, electrical signals including voltages and/or currents, waveform parameters (voltage, frequency, shape), optical measurements, infrared (IR) measurements, and temperature measurements, and other data. The controller 220 may process the data to reduce noise, calculate an average value, determine a difference or differential over a particular time frame, or any other useful process.

The controller 220 may be configured to provide data 238 to an AI unit 230. The data provided to the AI unit 230 may be processed by the controller 220 or it may represent the raw data provided to the controller by the one or more sensors 240. The AI unit 230 includes one or more processors 234 and memory 232 for storing computer instructions. The AI unit 230 operates in a logical fashion to perform operations, execute code configured to analyze data 238 provided by the control system by execution of computer code comprising an artificial intelligence program. Further, in carrying out the execution of such code, the AI unit 230 may provide control algorithms, store and retrieve data, interface with networks, and other desired operations. The AI unit 230 may include or be configured to access memory, primary storage devices, secondary storage devices, processors, networks, and any other components for executing code. The memory and secondary storage devices may be in the form of read-only memory (ROM) or random access memory (RAM) or integrated circuitry that is accessible by the controller. In some embodiments, the AI unit is also the controller 220. In such a case, the programming is run on the control unit 220 and so may not require separate memory and processor hardware. The AI unit 230 is configured to provide communication 236 back to the controller. This may include instructions for operation of the microreactor hardware 210. In some embodiments, the AI unit 230 interfaces directly with the microreactor hardware 210 and/or the one or more sensors 240.

The AI may be employed to build predictive models that can simulate the outcomes of experiments using the plasma microreactors. The experiments are multivariate, and may include a dozen or more parameters. A tremendous amount of data can be gathered during operation of the plasma microreactors. By analyzing the gathered data with an AI, the AI can assist with identification of patterns that a human may not readily perceive and make more accurate or counterintuitive predictions about how changing experimental parameters such as feed rates, pulse rate, frequency, and reactants, will affect outcomes.

With reference to FIG. 12, an AI may be used to automate the entire experimental process, from designing experiments to analyzing data. Autonomous experimentation systems can control system variables and parameters, and so can run experiments 24/7 while iterating through different conditions, enabling data collection much more quickly than would be possible with traditional experimentation methods.

As illustrated in FIG. 12, an AI 300 may be applied to interpretation of experimental data. In some embodiments, as illustrated in FIG. 12, the AI 300 includes an artificial neural network (ANN), which may include computer code executed by one or more processors. Experimental data is provided to one of more inputs 310 of the AI 300. The input data is processed by the AI, which may include one or more hidden neural network nodes 320, to produce one or more outputs 330. The data fed to the AI may include any of the information collected during the experiment include, though not limited to, feed rates of reactants and/or catalysts, flow rates of gas and liquid product streams, electrical signals including voltages and/or currents, waveform parameters (voltage, frequency, shape), optical measures, infrared (IR) measurements, and temperature measurements. Other data may also be provided.

The AI outputs may be further processed to create models to describe the behavior of the plasma microreactor. As illustrated in FIG. 12, the AI output may include a model of the catalytic activity as a function of one or more variables. In FIG. 12, for example, a topology of the catalytic activity as a function of the catalyst concentration and the activator concentration is represented as a three dimensional image. Other models may also be produced, such as catalyst activity, product flow rate, reaction rates, reaction efficiency, temperature, and any other desired output as a function of one of more inputs including (though not limited to) feed rates of reactants and/or catalysts, flow rates of gas and liquid product streams, electrical signals including voltages and/or currents, waveform parameters (voltage, frequency, shape), optical measures, infrared (IR) measurements, and temperature measurements. Such a model may be queried to determine optimal conditions for a desired output.

Returning to FIG. 11, the plasma microreactor hardware 210 can include processing circuitry configured to receive the sensor data 244 directly from the one or more sensors 240 or may be fed data 216 after the data has been gathered and processed by, for example, the control unit 220. The AI 230 may receive sensor data 244 238, either raw or processed, from the processing circuitry and may apply one or more machine learning models to the sensor data to generate a measurement of reactivity of the plasma with the reactants in the liquid phase. The AI of the AI unit 230 may suggest target values for at least one of the pulse rate or frequency of the electrical field generator, the temperature of the reactor, a flow rate of the reactants, or the concentration of the reactants responsive to the measurement of activity in the microreactor In some embodiments, the microreactor system includes processing circuitry configured to receive the sensor data from the one or more sensors, apply one or more machine learning models via the AI unit 230 to the sensor data and control a parameter of the operation of the microreactor. In some embodiments, the AI of the AI unit 230 is configured to directly control at least one of the pulse rate or frequency of the electrical field generator, the temperature of the reactor, a flow rate of the reactants, or the concentration of the reactants responsive to the measurement of activity in the microreactor. The AI, for example, may be able to send signals to the controller 220 or directly to the associated microreactor hardware 210 for any or each of these variables, thereby controlling a setpoint for the variable or an actual value for that variable.

The controller 220 and associated processing circuitry can be configured to directly or indirectly control the at least one of the pulse rate or frequency of the electrical field generator, the temperature of the reactor, a flow rate of the reactants, or the concentration of the reactants responsive to the measurement of activity in the microreactor to increase the measurement of reactivity or formation of desired products to be greater than a threshold measurement. The processing circuitry can be configured to use the machine learning model as a digital twin. A digital twin can include a process whereby a mathematic model (e.g., ANN) is used in lieu of a physical plasma microreactor to draw potentially relevant conclusions. For example, the algorithm can run the machine learning model as a digital twin and use the results to find a probable maximum.

### Example 1—Characterization of Plasma-Liquid Interface

Experiments were performed to characterize the plasma-liquid interface. Previous work has identified that plasma-liquid interface is influenced by the liquid surface tension, boiling point, vapor pressure, and dielectric constant.

A liquid phase comprising p-xylene and benzene was fed to a plasma microreactor. The configuration of the plasma microreactor was similar to that illustrated in FIG. 3, with several liquid and gas inlets available to receive feed streams. The microreactor included a microchannel with square corners that wound back and forth along the microreactor body. The microchannels were about 0.05 cm deep and 0.05 cm wide, and had total length of about 81 cm. Effluent was collected at an outlet of the reactor.

An organic liquid phase was supplied to a first liquid/gas inlet. A gas phase comprising either argon (Ar) or a mixture of argon and methane (Me) was fed to a second inlet of the microreactor. The methane/argon mixtures were 10%, 20%, 30%, and 40% methane by volume, with the balance of the gas feed to the microreactor being argon. For each feed composition, the voltage across the plasma microreactor was varied from 3 to 12 kV. The microreactor was operated at a 200 ns pulse width and a 10 kHz frequency.

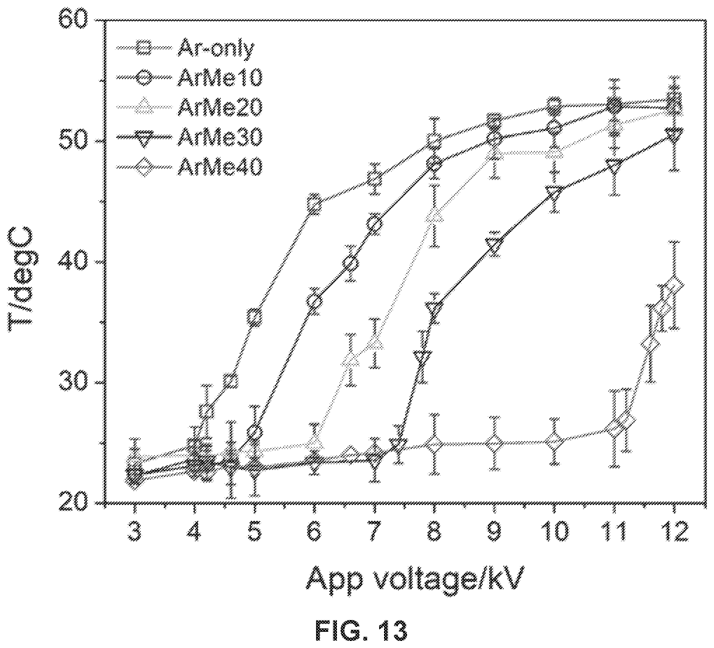

For each methane/argon mixture and for each voltage level, infrared measurements of the material in the reactor volume of the microreactor were taken. The infrared measurements were then used to calculate the temperature of the material in the reactor volume of the microreactor as a function of both the methane/argon composition of the gas and the voltage. The results are shown in FIG. 13. The increase in the temperature of the material is indicative of the plasma ignition. It was observed that, as the concentration of methane in the feed stream increases, an increasingly large voltage was required to produce a plasma within the reaction chamber of the microreactor.

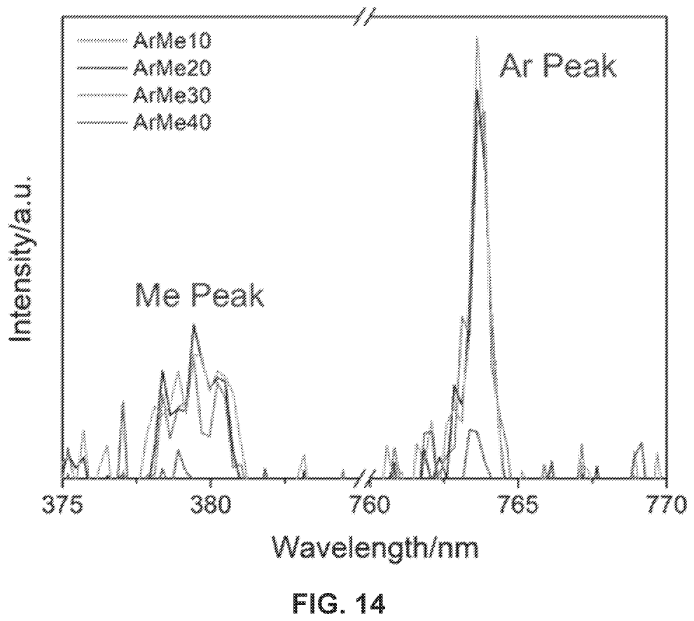

Optical emission spectroscopy was gathered for the microreactor while operating at 8 kV. The resulting OES spectra data for each Ar/Me feed mixture is shown in FIG. 14, with the expected Ar and Me spectral peaks indicated. Further, the flow behavior of the system was observed over a range of liquid and gas phase feed rates, whether the liquid plasma interface created slug or annular flow within the microreactor. The results are shown in FIG. 15A, with slug flow observed for lower gas feed rates (~0.1 mL/min) and annular flow being observed for gas feed rates of 1 mL/min or greater Sample images of the annular flow and slug flow behavior are shown in FIGS. 15B and 15C.

### Example 2—Synthesis of Methylated Cobaloxime

Experiments were performed for the methylization of cobaloxmine according to the following schematic:

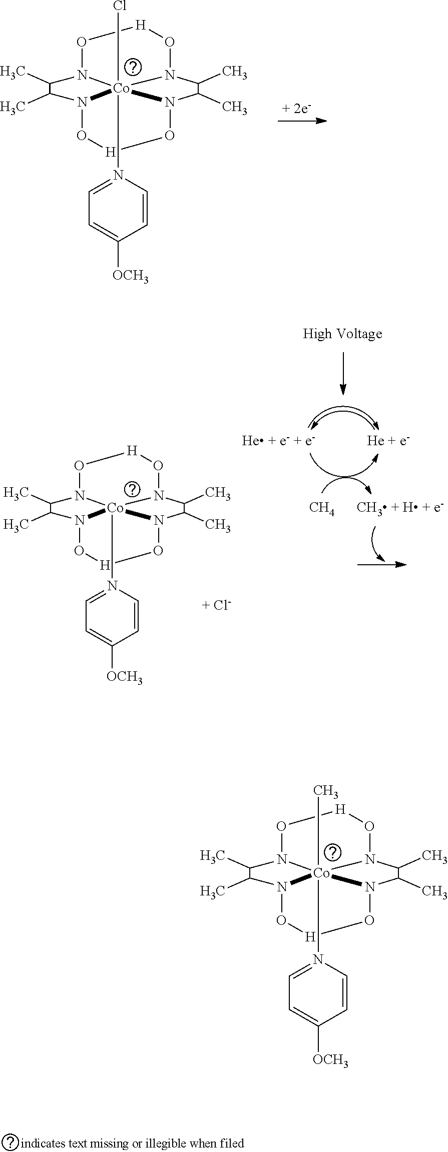

An atmospheric, dielectric-barrier discharge μ-plasmatron was designed, fabricated, and applied to synthesize a methylated organometallic complex. The design comprises counter-current flow to packed-bed microstructures to facilitate gas-liquid and plasma-liquid mixing. Micropillars arranged in a staggered configuration served as a porous media for the optimum 2D mixing of components that replenish plasma-liquid interfaces. Longitudinal dispersion was characterized through residence time distribution (RTD) measurements. The experimental RTD data were then described by an axial dispersion model with a time delay parameter. Levenspiel number (Iv) indicating the intensity of axial dispersion was estimated in the range of 20.1-374, indicating that a dispersion model should be accounted for in plasma-assisted reaction kinetics development. Stable plasma excitation of methane-helium gas mixtures was observed within the 2D porous media, by in-situ optical emission spectra, while applying an alternating high voltage across the dielectric barrier. This novel technique made it possible to confirm in-situ formations of methyl radicals. Interestingly, the porous media served as a static mixer as no discrete plasma streamers were observed. To investigate its utility, an example homogeneous cobalt catalyst was injected into the μ-plasmatron and methylated.

The μ-plasmatron was fabricated from a 1 mm thick single crystal silicon wafer and a 1.1 mm thick borosilicate glass wafer (BOROFLOAT® 33). The fabrication process primarily included the following microelectronics processing techniques: (a) photolithography to prepare etching patterns on the silicon wafer; (b) deep reactive ion etching to create reactor channels, the depth of which is determined by Filmetrics F20 Thin Film Analyzer; (c) piranha clean to remove organic substance from substrate; (d) plasma-enhanced chemical vapor deposition to implement a thin layer of silicon nitride as additional dielectric discharge barrier, the thickness of which is determined by Bruker Dektak-XT Stylus Profiler; (e) anodic bonding of the silicon wafer to the glass wafer; (f) sputter coating to deposit chromium thin layers on top and bottom of the reactor to create μ-plasmatron electrodes. (g) dicing into chips.

The thickness of the silicon nitride layers wrapping around silicon wafer was 2 μm. The thicknesses of the chromium electrode sputtered on the top and bottom of the membrane area were 20 nm. The depth of discharge gap was 500 μm. The liquid streams would enter the μ-reactor through the two inlets in the middle, then passed a serpentine channel before entering the packed-bed for the optimal liquid-phase mixing. The mixed gas flowed into the μ-reactor through its inlet on the right, then entered the packed-bed, counter-current via the micro-membranes on the top and bottom of the packed bed. The chromium thin electrodes were aligned above and below the membranes, in which region the nonthermal plasma The μ-plasmatron was fabricated from a 1 mm thick single crystal silicon wafer and a 1.1 mm thick borosilicate glass wafer (BOROFLOAT® 33). The fabrication process primarily included the following microelectronics processing techniques: (a) photolithography to prepare etching patterns on the silicon wafer; (b) deep reactive ion etching to create reactor channels, the depth of which is determined by Filmetrics F20 Thin Film Analyzer; (c) piranha clean to remove organic substance from substrate; (d) plasma-enhanced chemical vapor deposition to implement a thin layer of silicon nitride as additional dielectric discharge barrier, the thickness of which is determined by Bruker Dektak-XT Stylus Profiler; (e) anodic bonding of the silicon wafer to the glass wafer; (f) sputter coating to deposit chromium thin layers on top and bottom of the reactor to create μ-plasmatron electrodes. (g) dicing into chips. The thickness of the silicon nitride layers wrapping around silicon wafer was 2 μm. The thicknesses of the chromium electrode sputtered on the top and bottom of the membrane area were 20 nm. The depth of discharge gap was 500 μm. The liquid streams would enter the μ-reactor through the two inlets in the middle, then passed a serpentine channel before entering the packed-bed for the optimal liquid-phase mixing. The mixed gas flowed into the μ-reactor through its inlet on the right, then entered the packed-bed, counter-current via the micro-membranes on the top and bottom of the packed bed. The chromium thin electrodes were aligned above and below the membranes, in which region the nonthermal plasma

The silicon-glass reactor was compressed against chemical resistant Viton® O-rings to form a fluidic connection to the polyether ether ketone (PEEK) base, which was machined for standard high-pressure fittings to connect to external fluid delivery system. The top resin clamp, base PEEK chuck, screws and fittings were all made of electric insulating materials. A Teledyne ISCO syringe pump (Model 65D) delivered the gas at constant flow rates or pressures while a Harvard PHD 2000 syringe pump delivered the liquid streams. Pressures in the μ-plasmatron were regulated by an Equilibar ZF Series precision back-pressure regulator. Pressure was also monitored and recorded at each stream before entering the μ-reactor by pressure transmitters connected to a National Instruments data acquisition system. Elevated pressure tests were performed in stainless steel compression fittings. A glass block was placed between reactor top and top clamp for evenly distributed pressure on the microchip.

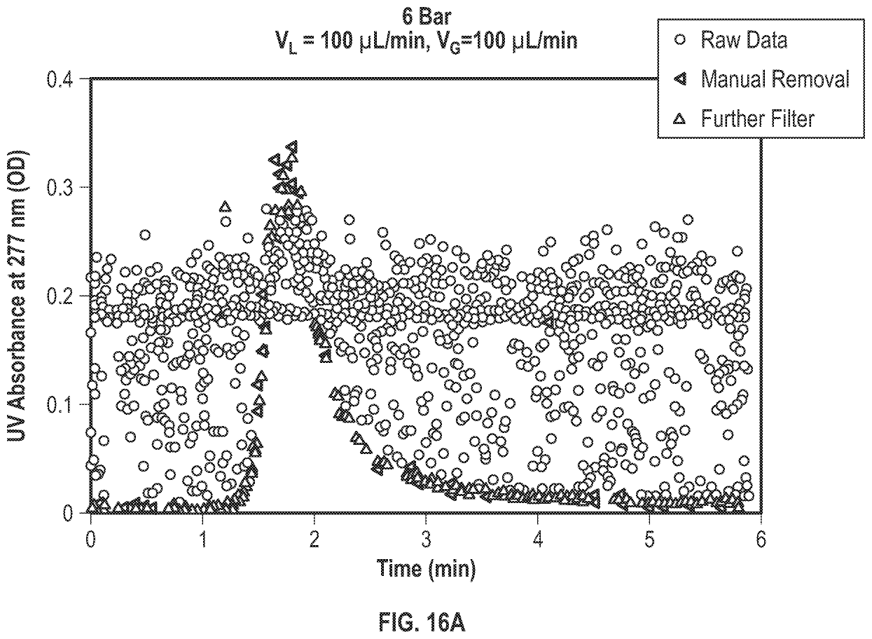

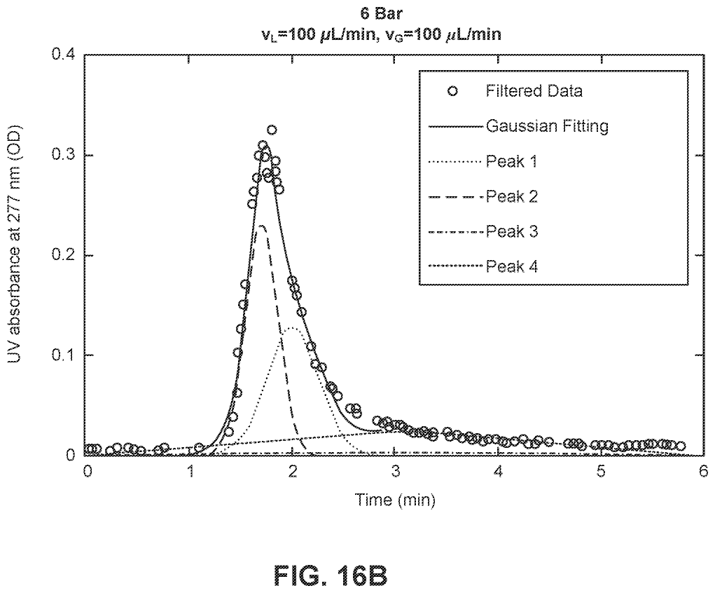

The residence time distributions (RTDs) were obtained from a pulse injection of acetone in the liquid phase. Reproducible pulse injections were made possible using a 5 μl tracer loop mounted on a switching six-way valve (Rheodyne 8125). UV absorbance at 277 nm was then collected immediately downstream of the microfluidic outlet using a flow cell. UV emissions were generated by an Ocean Optics UV-VIS-NIR light source (DH-2000-BAL) with both deuterium and halogen lamps turned on. UV signals were transmitted through two Ocean Optics UV-VIS fibers (QP400-2-UV-VIS, 2.00 m length) with monocoil jacketing and SMA connections. UV absorptions were detected by an Ocean Optics miniature spectrometer (FLAME-S-UV-VIS-ES) and then read using the Ocean View Spectroscopy software. Methane total volumetric flow rates of 50, 100, 150, 200 μl min−1 and gas-to-liquid volumetric ratios of 0.25:1, 0.33:1, 0.5:1, 0.67:1, 0.75:1, 1:1, 1.33:1, 1.5:1, 2:1, 3:1, and 4:1 were studied for pressures in the range of 2, 4, 6, and 8 bar to fully map out the reactor dispersion characteristics. Each gas-liquid flow rate ratios were tested both with and without any tracer to decouple the RTD from the raw data. RTDs at atmospheric pressure and low flow rates, total volumetric flow rates of 0.75 μl min−1 and 1.5 μl min−1, were measured as conditions relevant to plasma experiments. The corresponding ideal reactor packedbed space times are 23.3 and 11.7 min for methane-to-water volumetric ratios of 1:3, 1:1, and 3:1. Gas slugs passing through the UV detector, as expected, would generate a pulse noise signal scattering at around 0.2 OD on the UV absorbance spectrum, which made decoupling of gas signals from RTD measurements critical. An example UV-absorbance spectrum collected under 6 bar and at a water flow rate of 100 μl min−1 and methane flow rate of 100 μl min−1 is shown in FIG. 16B. RTD experiments with only liquid in the system at 50, 100, 150, 200 μl min−1 total volumetric flow rate, under 2, 4, 6, 8 bar and 0.75, 1.5 μl min−1 flow rate, atmospheric pressure was also performed as comparisons.

Since the volume of chuck and external connections were significant compared to that of the reactor, RTDs of chuck were evaluated as well by connecting ports on the chuck using a piece of chip that contained only one straight microchannel.

Gas-liquid distributions within the packed bed were also measured at different pressures and gas-to-liquid volumetric flow rate ratios at ambient temperature under a microscope to study the liquid hold-ups at steady state. Microscope images (10×) at different locations along the packed bed were taken individually along a preset path and collaged together using LabSpecs 6.0 Mosaic package to represent the entire reactor.

High-voltage breakdown across the capillary array was realized by applying alternating high voltages on Cr electrodes deposited on the reactor top and bottom surfaces. During the experiments, up to 10 k V were applied at less than 10 mA. The chromium electrodes on top and bottom of the reactor were wired to the external circuit using two set of alligator clip. To complete the circuit and form voltage difference across the reactor, one side of the alligator clamps were wrapped with polyimide tape for insulation while the other side was wrapped with copper tape for better contact with the thin layer electrodes and optimum electricity conduction. Alligator clips that were connected to high voltage and grounding were clamped to the reactor in opposite directions. Insulating tape was also applied to the edge of the reactor to eliminate any possible arcing through the sides. Signal frequencies and shapes were generated by a waveform function generator (AFG 3021C by Tektronix) and then sent to a high voltage power supply (AMP 10B10 by Matsusada) to be further amplified. The signals were then magnified by 1000 times, and the resulting high voltages are applied to the electrodes on the top side of the reactor. The electrodes on the bottom side were grounded to the same point as the amplifier to complete the circuit. The specific grounding wires (DABURN #2473 FEP High Voltage Wire) used were silver plated soft copper conductors insulated with FEP, consisting of a smaller diameter compared to wires meeting the same ratings. The current was measured by a current probe (Tektronix P6021A) at the grounding end, while voltages were measured by a high voltage probe (Tektronix P6015A). Measured signals were recorded on an oscilloscope (Tektronix DPO 2014B) and data was further extracted through the Tektronix OpenChoice application.

A literature survey of methane microplasmas identified that the majority of the prior art had focused on generation of plasma with a rich noble gas with less than 20% methane. Thus, the prior art was used to guide our experimental conditions. The addition of noble gases considerably increases the electron temperature, resulting in increased electron density, and eventually enhanced plasma ionization and dissociation. The presence of 85% of helium has also been reported to significantly increase the energy efficiency for methane excitation compared to pure methane, and no significant difference between helium and argon on the conversion of methane was observed. The helium rich mixed gas (16.6 vol. % methane and 83.3 vol. % helium) was injected into the device by an ISCO syringe pump (TELEDYNE 65D), while liquids were delivered by a syringe pump (Harvard Apparatus PHD 2000). An emergency stop button was also designed for an emergency shutdown to the circuit. Properly rated flame resistant and arc preventing personal protective equipment, including an insulation mat, were required at any point during the operation of high voltages.

Plasma light emissions were collected by an optical fiber (400 μm core diameter) positioned above the μ-plasmatron at a 30 mm distance. Metal connections on the optical fiber were grounded to the same point as all other high voltage equipment to prevent damage. Light signals were processed by an optical spectrometer (200-800 nm range, 12 nm resolution).

Co(dmgH)2(4-O-Me-py)Cl was prepared following a reported procedure. Co(dmgH)2(4-O-Me-py)Cl dichloromethane solution (0.015 mmol ml−1) was injected into the μ-plasmatron at a flow rate of 10 μl min−1 with the other liquid inlet plugged. Mixed gas (16.6% methane and 83.3% helium) was injected at a flow rate of 1 μl min−1. The total residence time of chemicals in the μ-reactor was 1.5 min. Sine-shaped alternating high voltages with 9 kV peak-to-peak amplitude and 10 kHz frequencies was applied on the μ-plasmatron for stable plasma generation to study the addition of methyl radicals to the center of cobalt complex. Effluent was collected using a 1.5 ml borosilicate glass vial and then dried in vacuum to harvest the remaining crystals. The solids were then placed on a silicon wafer and its composition was determined in a LabRAM HR Evolution RAMAN Spectrometer under a 532 nm laser (laser power 50 mW) at 15 s acquisition time with denoiser turned on.

Results showing the mean residence time, deviation, and calculated Levenspiel numbers for the reactor conditions are shown in Tables 1 and 2 below.

TABLE 1
Reactor dispersion of two-phase flow for elevated flow rates at 2, 4, 6 and 8 bar.

| | | | Measured | | | | |
|---|---|---|---|---|---|---|---|
| | Water | Methane | mean | | Modeled | | |
| | flow | flow | residence | | dead | | |
| | rate [symbol] | rate [symbol] | time | | time | | [symbol] |
| Pressure | (μl | (μl | [symbol] | [symbol] | [symbol] | Fraction of | number |
| (bar) | min⁻¹) | min⁻¹) | (min) | (min²) | (min) | dead time d | [symbol] |
| 2 | 50 | 50 | 12.14 | 18.84 | −3.14 | 0.26 | 15.4 |
| | | 100 | 12.13 | 10.01 | −1.09 | 0.09 | 29.3 |
| | | 150 | 3.29 | 1.21 | −0.29 | 0.06 | 46.3 |
| | | 200 | 3.89 | 1.06 | −0.07 | 0.02 | 28.6 |
| | 100 | 50 | 3.26 | 0.13 | −0.65 | 0.20 | 164.0 |
| | | 100 | 4.76 | 0.18 | −0.21 | 0.04 | 258.4 |
| | | 150 | 5.12 | 0.14 | −0.20 | 0.04 | 374.4 |
| | | 200 | 2.73 | 0.14 | −0.14 | 0.05 | 110.3 |
| | 150 | 50 | 1.34 | 0.07 | −0.56 | 0.42 | 53.4 |
| | | 100 | 1.26 | 0.06 | −0.82 | 0.66 | 50.5 |
| | | 150 | 1.37 | 0.07 | −0.27 | 0.19 | 56.2 |
| | | 200 | 3.37 | 0.23 | −1.87 | 0.56 | 98.0 |
| | 200 | 50 | 0.82 | 0.02 | −0.55 | 0.67 | 71.4 |
| | | 100 | 1.37 | 0.06 | −0.04 | 0.03 | 61.5 |
| | | 150 | 0.93 | 0.03 | −0.83 | 0.89 | 50.5 |
| | | 200 | 1.03 | 0.04 | −0.35 | 0.34 | 54.1 |
| 4 | 50 | 50 | 4.00 | 0.40 | −0.32 | 0.08 | 79.5 |
| | | 100 | 6.79 | 0.90 | −0.44 | 0.07 | 102.6 |
| | | 150 | 1.67 | 0.18 | −0.14 | 0.08 | 30.6 |
| | | 200 | 0.27 | 0.00 | −0.35 | 1.29 | 83.2 |
| | 100 | 50 | 2.31 | 0.13 | −0.42 | 0.18 | 81.9 |
| | | 100 | 2.40 | 0.19 | −0.81 | 0.34 | 61.2 |
| | | 150 | 1.88 | 0.13 | −0.17 | 0.09 | 53.5 |
| | | 200 | 2.02 | 0.10 | −0.34 | 0.17 | 79.8 |
| | 150 | 50 | 1.39 | 0.07 | −0.24 | 0.18 | 58.8 |
| | | 100 | 1.45 | 0.07 | −0.64 | 0.44 | 57.0 |
| | | 150 | 1.28 | 0.05 | −0.42 | 0.33 | 59.8 |
| | | 200 | 1.30 | 0.05 | −0.34 | 0.26 | 66.3 |
| | 200 | 50 | 1.01 | 0.03 | −0.42 | 0.42 | 67.1 |
| | | 100 | 0.95 | 0.03 | −0.61 | 0.64 | 52.7 |
| | | 150 | 1.25 | 0.04 | −0.61 | 0.49 | 72.1 |
| | | 200 | 1.25 | 0.04 | −0.77 | 0.61 | 77.7 |
| 6 | 50 | 50 | 3.71 | 0.18 | −0.32 | 0.09 | 150.5 |
| | | 100 | 2.00 | 0.42 | −0.39 | 0.20 | 19.0 |
| | | 150 | 4.07 | 0.27 | −0.31 | 0.07 | 121.9 |
| | | 200 | 3.62 | 0.47 | −0.44 | 0.12 | 55.1 |
| | 100 | 50 | 2.55 | 0.12 | −0.47 | 0.19 | 105.1 |
| | | 100 | 1.84 | 0.07 | −0.39 | 0.21 | 93.6 |
| | | 150 | 1.87 | 0.09 | −0.72 | 0.39 | 77.9 |
| | | 200 | 3.11 | 0.28 | −0.25 | 0.08 | 68.4 |
| | 150 | 50 | 1.29 | 0.06 | −0.45 | 0.33 | 57.8 |
| | | 100 | 1.64 | 0.09 | −0.52 | 0.32 | 60.2 |
| | | 150 | 1.22 | 0.05 | −0.47 | 0.39 | 57.0 |
| | | 200 | 1.28 | 0.06 | −0.60 | 0.46 | 59.4 |
| | 200 | 50 | 1.00 | 0.03 | −0.48 | 0.48 | 65.9 |
| | | 100 | 0.83 | 0.03 | −0.70 | 0.85 | 51.6 |
| | | 150 | 1.01 | 0.04 | −0.21 | 0.21 | 55.4 |
| | | 200 | 1.10 | 0.03 | −0.96 | 0.87 | 77.6 |
| 8 | 50 | 50 | 3.88 | 1.019 | −1.51 | 0.26 | 67.7 |
| | | 100 | 3.90 | 0.310 | −0.78 | 0.20 | 98.3 |
| | | 150 | 6.37 | 12.684 | −4.72 | 0.74 | 6.0 |
| | | 200 | 3.47 | 0.251 | −0.27 | 0.08 | 96.0 |
| | 100 | 50 | 2.20 | 0.125 | −0.53 | 0.24 | 77.6 |
| | | 100 | 1.67 | 0.046 | −0.01 | 0.00 | 123.0 |
| | | 150 | 1.88 | 0.071 | −1.80 | 0.96 | 98.9 |
| | | 200 | 2.00 | 0.148 | −0.45 | 0.22 | 54.0 |
| | 150 | 50 | 1.42 | 0.059 | −0.42 | 0.30 | 68.6 |
| | | 100 | 1.64 | 0.098 | −0.58 | 0.35 | 55.1 |
| | | 150 | 1.23 | 0.055 | −0.14 | 0.11 | 54.3 |
| | | 200 | 1.45 | 0.053 | −0.61 | 0.42 | 79.2 |
| | 200 | 50 | 1.14 | 0.052 | −0.47 | 0.41 | 50.5 |
| | | 100 | 1.11 | 0.025 | −1.71 | 1.54 | 97.5 |
| | | 150 | 0.99 | 0.031 | −0.71 | 0.72 | 63.3 |
| | | 200 | 1.19 | 0.052 | −1.30 | 1.09 | 54.9 |

[symbol]

indicates data missing or illegible when filed

TABLE 2
Reactor dispersion with only liquid and mixtures gas and liquid in the system at low flow rates.

| | Ideal | | Measured | | | | | | | |
|---|---|---|---|---|---|---|---|---|---|---|
| Total | packed | | mean | | | | | | | |
| volumetric | bed space | Q_{L}/Q_{G} | residence | | Modeled dead | | Fraction of | | [symbol] | |
| flow | time | for two | time [symbol] (min) | | time [symbol] (min) | | dead time [symbol] | | number [symbol] | |
| rate [symbol] | [symbol] | phase | | Gas and | | Gas and | | Gas and | | Gas and |
| (μl min⁻¹) | (min) | flows | Liquid | liquid | Liquid | liquid | Liquid | liquid | Liquid | liquid |
| 0.75 | 23.3 | 0.33 | 543.4 | 738.9 | −39.5 | −28.9 | 0.07 | 0.04 | 58.9 | 20.1 |
| | | 1 | | 579.6 | | −48.7 | | 0.08 | | 42.1 |
| | | 3 | | 293.7 | | −38.4 | | 0.13 | | 22.7 |
| 1.5 | 11.7 | 0.33 | 299.5 | 534.6 | −24.1 | −26.7 | 0.08 | 0.05 | 68.7 | 41.9 |
| | | 1 | | 291.8 | | −16.5 | | 0.06 | | 94.8 |
| | | 3 | | 250.7 | | −9.9 | | 0.04 | | 86.0 |

[symbol]

indicates data missing or illegible when filed

Tracer experiments were performed to characterize the residence time distribution (RTD) with gas and liquid multiphase flows as a simplified model. The resultant UV-absorbance data was decoupled by first manually removing gas signals in a signal processing software package, followed by utilizing a median filter to further remove remaining noises. The processed signals were then fitting into Gaussian models to extract smoothed curves, which led to more accurate results of the curve normalizations. An example of noise removal from the raw data is shown in FIG. 16A, and an example of data fitting by Gaussian models is reported in FIG. 16B. It is important to note that each of the peak components in one Gaussian fitting here do not necessarily represent actual physically meanings of the system. Also note that the Gaussian models were only optimized to represent those curves from liquid RTDs as the tracer only exists within the liquid phase with any partitioning into the gas phase being negligible. The extracted RTD curves were then used to evaluate the mean residence times tm and longitudinal dispersion indicated by Levenspiel number, Iv.

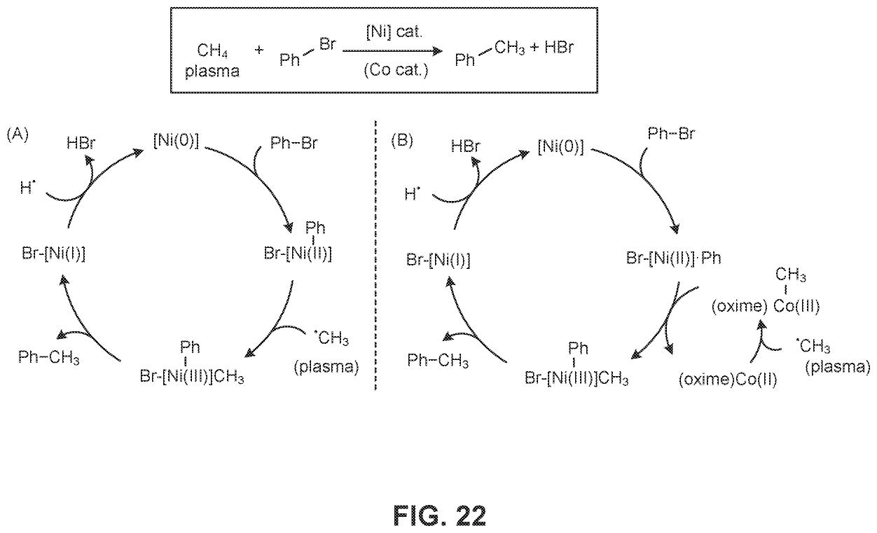

The vitamin B12 model compounds cobaloximes as active catalysts have shown high electro- and photoactivity in photocatalysis. The addition of radicals to Co(II) center and cleavage of Co(III)—C bonds have also been widely studied. The cobalt complex Co(dmgH)2(4-O-Mepy) Cl was selected as the model substrate for a methyl radical addition study. Photoredox/organo-metallic cooperative catalysis in which photoexcited Ir catalyst first accomplishes oneelectron reduction of Co or Ni, which then accepts alkyl radicals produced from oxidation of alkyl carboxylates by oxidant Ir, are started to be studied very recently. A similar route in which the photoredox cycle is replaced by a plasmonic cycle is proposed for the formation of methylated cobaloxime and is shown in FIG. 22. In this mechanism, electrons from the discharge streams or dissociated from helium first reduce the Co (III) to Co (II), then the Co (II) center accepts methyl radicals from plasma, forming methylated Co (III) compound. This reaction has the potential in the direct addition of methyl groups to organic compounds mediated by cobaloximes.

In the present work, 0.01 mmol ml−1 Co(dmgH) 2(4-O-Mepy) Cl in dichloromethane solution was injected into the μ-reactor at a flow rate of 10 μl min−1, with 83% methane/17% helium mixed gas flowing through at a flow rate of 1 μl min−1, giving a 1.5 min residence time in the packed-bed. Solutions of both no voltages applied, and 9 kV voltages applied on the μ-plasmatron were collected at the outlet and then dried in vacuum. The remaining crystals were then put onto a piece of silicon wafer for Raman tests with 532 nm laser. The results are shown in FIG. 16B.

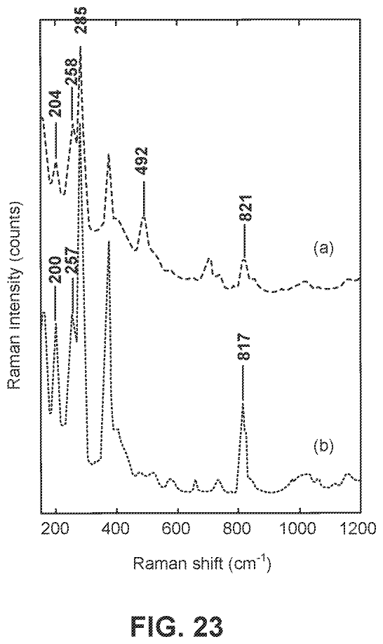

The stretching frequency of Co—CH3 in the solid state has usually been found at around 500 cm−1, and it could be shifted by the trans-axial ligand L (the stronger electron donating L results in the smaller Co—CH3 stretching frequencies). The Co—CH3 stretch at a range between 455 cm−1 and 522 cm−1 was reported in previous research for a variety of ligand species. This vibrational frequency is unique for L-Co—CH3 cobaloximes and is not observed in L-Co—Cl B12 vitamin models. As can be seen in FIG. 23, Co—CH3 stretch at 492 cm−1 was found in the plasma treated cobaloxime, suggesting the formation of methyl-cobalt bond. The low frequency bands at 204 cm−1 in and 200 cm−1 in FIG. 23 are likely to be the L-Co—CH3 and the L-Co—Cl bending frequencies (δL-Co—CH3 and δL-Co—Cl), which are consistent with those observed at 186 cm−1 and 194 cm−1 previously. The bands at 258 cm−1 and 285 cm−1 and bands at 257 cm−1 and 285 cm−1 in FIG. 19 were from Co—N(py) stretches. The bands at around 580 cm−1 were from the C═N—O deformation on dimethylglyoxime, while the bands at 821 cm−1 and 817 cm−1 in FIG. 16B were from skeletal deformation of dimethylglyoxime. These findings undergird the exciting prospects of methane plasmas in organometallic synthesis. In the context plasma physics, flash chemistry is now possible with multiphase μ-plasmatrons where transport limitations in conventional reactor designs could be expected to influence the overall rate of reaction.

### DEFINITIONS

As used herein, the singular forms “a,” “an,” and “the” include plural referents unless the context clearly dictates otherwise. Thus, for example, the term “a member” is intended to mean a single member or a combination of members, “a material” is intended to mean one or more materials, or a combination thereof.

As used herein, the terms “about” and “approximately” generally mean plus or minus 10% of the stated value. For example, about 0.5 would include 0.45 and 0.55, about 10 would include 9 to 11, about 1000 would include 900 to 1100.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

As used herein, the terms “coupled,” “connected,” and the like mean the joining of two additional intermediate members being integrally formed as a single unitary body with one another or with the two members or the two members and any additional intermediate members being attached to one another.

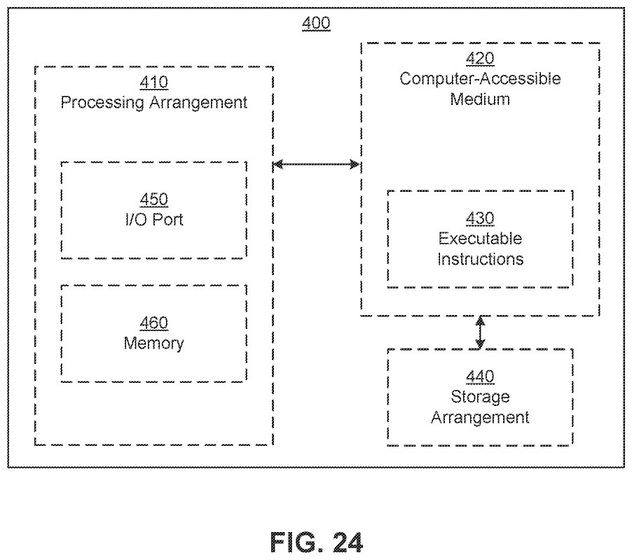

As shown in FIG. 24 storage for a computational system 400, such as the controller and/or the AI unit previously described, may include a computer-accessible medium 420 (e.g., as described herein, a computer-readable storage device, a computer-readable storage substrate, a random or serial access memory array or device, or a combination of one or more of them) may include more than one storage members directly or indirectly connected to one another. Such joining may be stationary (e.g., permanent) or moveable (e.g., removable or releasable). Such joining may be achieved with the two members or the two members and any device such as a hard disk, floppy disk, memory stick, CD-ROM, RAM, ROM, etc., or a collection thereof) can be provided (e.g., in communication with the processing arrangement 410). The computer-accessible medium 420 may be a non-transitory computer-accessible medium. The computer-accessible medium 420 can contain executable instructions 430 thereon. In addition or alternatively, a storage arrangement 440 can be provided separately from the computer-accessible medium 420, which can provide the instructions to the processing arrangement 410 so as to configure the processing arrangement to execute certain exemplary procedures, processes and methods, as described herein, for example. The instructions may include a plurality of sets of instructions.

System 400 may also include a display or output device, an input device such as a keyboard, mouse, touch screen or other input device, and may be connected to additional systems via a logical network. Many of the embodiments described herein may be practiced in a networked environment using logical connections to one or more remote computers having processors. Logical connections may include a local area network (“LAN”) and a wide area network (“WAN”) that are presented here by way of example and not limitation. Such networking environments are commonplace in office-wide or enterprise-wide computer networks, intranets and the Internet and may use a wide variety of different communication protocols. Those skilled in the art can appreciate that such network computing environments can typically encompass many types of computer system configurations, including personal computers, hand-held devices, multi-processor systems, microprocessor-based or programmable consumer electronics, network PCs, minicomputers, mainframe computers, and the like. Embodiments of the invention may also be practiced in distributed computing environments where tasks are performed by local and remote processing devices that are linked (either by hardwired links, wireless links, or by a combination of hardwired or wireless links) through a communications network. In a distributed computing environment, program modules may be located in both local and remote memory storage devices.

Various embodiments are described in the general context of method steps, which may be implemented in one embodiment by a program product including computer-executable instructions, such as program code, executed by computers in networked environments. Generally, program modules include routines, programs, objects, components, data structures, etc. that perform particular tasks or implement particular abstract data types. Computer-executable instructions, associated data structures, and program modules represent examples of program code for executing steps of the methods disclosed herein. The particular sequence of such executable instructions or associated data structures represents examples of corresponding acts for implementing the functions described in such steps.

Software and web implementations of the present invention could be accomplished with standard programming techniques with rule-based logic and other logic to accomplish the various database searching steps, correlation steps, comparison steps and decision steps. It should also be noted that the words “component” and “module,” as used herein and in the claims, are intended to encompass implementations using one or more lines of software code, and/or hardware implementations, and/or equipment for receiving manual inputs.

It is important to note that the construction and arrangement of the various exemplary embodiments are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. Other substitutions, modifications, changes and omissions may also be made in the design, operating conditions and arrangement of the various exemplary embodiments without departing from the scope of the present invention.

While this specification contains many specific implementation details, these should not be construed as limitations on the scope of any inventions or of what may be claimed, but rather as descriptions of features specific to particular implementations of particular inventions. Certain features described in this specification in the context of separate implementations can also be implemented in combination in a single implementation. Conversely, various features described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.
Embodiment 1: A method of producing a chemical product, the method comprising: providing a first plasma reactor comprising: a reaction volume in liquid communication with a first inlet, a second inlet, and an outlet, the reaction volume including reaction channels to direct a flow of liquids within the first plasma reactor; a first electrode positioned adjacent at least a portion of a first side of the reaction volume; and a second electrode positioned adjacent at least a portion of the second side of the reaction volume; providing an electrical field generator electrically connected to the first electrode of the first plasma reactor and to the second electrode of the first plasma reactor, and operating the electrical field generator to generate an electrical field across at least a portion of the reaction volume of the first plasma reactor; feeding a first stream containing a first chemical reactant in a gaseous state through the first inlet of the first plasma reactor into the reaction volume such that at least a portion of the first stream contacts at least one of the first electrode and the second electrode and generates a non-thermal plasma within the reaction volume of the first plasma reactor, feeding a second stream containing a second chemical reactant in a liquid state into the reaction volume through the second inlet of the first plasma reactor, controlling properties of the non-thermal plasma through adjustment of a waveform, pulse rate, amplitude, or voltage of the electrical field generated by the electrical field generator; and collecting a product stream containing the chemical product from the outlet of the first plasma reactor
Embodiment 2: The method of embodiment 1, wherein the reaction channels include at least one of microfluidic channels and millifluidic channels.
Embodiment 3: The method of embodiment 2, wherein the reaction channels are shaped to establish microfluidic flow of the first chemical reactant and the second chemical reactant.
Embodiment 4: The method of any one of embodiments 1-3, wherein the first chemical reactant is methane.
Embodiment 5: The method of any one of embodiments 1-4, wherein the second chemical reactant is an aryl heteroatom; an aryl amine, a di-aryl compound, an alkane, an alkene, an aryl, or an amine, polymers, an organometallic complex, a fine chemical, or a pharmaceutical precursor.
Embodiment 6: The method of any one of embodiments 1-5, wherein the second stream also contains a catalyst.
Embodiment 7: The method of embodiments 6, wherein the catalyst comprises an organometallic catalyst or a transition metal complex.
Embodiment 8: The method of either of embodiment 6 or 7, wherein the catalyst includes at least one of cobalt, nickel, palladium, copper, nickel, platinum, titanium, titanium dioxide, rubidium, rhodium, or iridium.
Embodiment 9: The method of embodiment 8, further including applying a machine learning module to data collected during operation of the first plasma reactor and changing at least one of a first stream flow rate, a second stream flow rate, the first chemical reactant, the second chemical reactant, the catalyst in the second stream, and the waveform, pulse rate, amplitude or voltage provided by the electrical field generator based on the machine learning module.
Embodiment 10: The method of embodiment 9, wherein the data collected during operation of the first plasma reactor includes one or more of optical data, dynamic light scattering (DLS) data, optical emission spectroscopy (OES) data, UV-visible optical absorption spectroscopy (OAS) data, infrared (IR) data, infrared photonic data, infrared thermography data, temperature data, mass spectrometry (MS) data, and nuclear magnetic resonance (NMR) data.
Embodiment 11: The method of any one of embodiments 1-10, also including: feeding the collected product stream into a second plasma reactor second inlet, wherein the second plasma reactor includes: a second plasma reactor reaction volume in liquid communication with a second plasma reactor first inlet, the second plasma reactor second inlet, and a second plasma reactor outlet, the second plasma reactor reaction volume including second plasma reactor reaction channels to direct the flow of liquids within the second plasma reactor; a second plasma reactor first electrode positioned adjacent at least a portion of a first side of the second plasma reactor reaction volume; and a second plasma reactor second electrode position adjacent at least a portion of a second side of the second plasma reactor reaction volume; providing the electrical field generator electrically connected to the first electrode of the second plasma reactor and to the second electrode of the second plasma reactor, and operating the electrical field generator to generate the electrical field across at least a portion of the reaction volume of the second plasma reactor; feeding a third stream containing a third chemical reactant in a gaseous state through the first inlet of the second plasma reactor into the reaction volume such that at least a portion of the first stream contacts at least one of the first electrode and the second electrode of the second plasma reactor and generates a plasma within the reaction volume of the second plasma reactor, and collecting a second product stream containing a second chemical product from the outlet of the second plasma reactor.
Embodiment 12: The method of any one of embodiments 1-11, also including linking one or more additional plasma reactors in series with the first plasma reactor and with a final plasma reactor, such that at least one of the one or more additional plasma reactors receives as an input at least a portion of the product stream from the first plasma reactor and the final plasma reactor receives as an input at least a portion of a product stream from at least one of the one or more additional plasma reactors.
Embodiment 13: The method of any one of embodiments 1-12 also including linking one or more additional plasma reactors in parallel with the first plasma reactor.
Embodiment 14: The method of embodiment 13 also including operating one or more additional plasma reactors in parallel with the first plasma reactor and applying a machine learning module to data collected during operation of at least one of the first plasma reactor and the one or more additional plasma reactors, and changing an operating parameter of at least one of the first plasma reactor and the one or more additional plasma reactors based on the machine learning module.
Embodiment 15: The method of any one of embodiments 1-14, wherein the reaction channels comprise an upper wall at least partially formed of a first material and a lower wall at least partially formed a second material, wherein the first material is selected from a metal, a dielectric, a semiconductor, a conductor, or a combination, or a laminate of any two or more thereof.
Embodiment 16: The method of embodiment 15, wherein the reaction channels comprise at least one transparent side and the method further comprises collecting optical data or infrared data through at least one of the first material and the second material.
Embodiment 17: A method of hydroalkylation of a chemical reactant, the method comprising: providing a liquid phase comprising an organometallic catalyst and the chemical reactant; exposing a hydrocarbon to an electric field to generate a low temperature alkyl plasma; and interfacing the low temperature alkyl plasma with the liquid phase.
Embodiment 18: The method embodiment 17, wherein the liquid phase and the hydrocarbon are fed through a reaction channel having microchannels and the electric field is applied across the microchannels.
Embodiment 19: The method of embodiment 18, wherein the reaction channel comprises an upper wall at least partially formed of a first material and a lower wall at least partially formed of a second material, wherein the reaction channel comprises at least one transparent side; and wherein the method further comprises collecting optical data or infrared data through at least one of the first material and the second material
Embodiment 20: A method of determining a chemical reaction coefficient for a plasma-liquid reaction system, the method comprising: feeding a first stream containing a first chemical reactant in a gaseous state at a gaseous volumetric feed rate to a reaction volume of a plasma reactor, feeding a second stream containing a second chemical reactant in a liquid state at a liquid volumetric feed rate into the reaction volume; providing an electrical field across at least a portion of the reaction volume to generate a non-thermal plasma within the reaction volume of the plasma reactor; determining a liquid hold up (epsilon) according to the gaseous volumetric feed rate and the liquid volumetric feed rate; adjusting at least one of the gaseous volumetric feed rate and the liquid volumetric feed rate to determine an optimum epsilon value that corresponds to one of a plasma ignition event or a plasma extinction event, wherein the plasma ignition event or the plasma extinction event is determined by infrared thermography; determining a mass transfer coefficient according to the optimum epsilon value; and determining the chemical reaction coefficient according to the mass transfer coefficient.

Other embodiments are set forth in the following claims, along with the full scope of equivalents to which such claims are entitled.

What is claimed is:

1. A method of producing a chemical product, the method comprising:
providing a first plasma reactor comprising:
a reaction volume in liquid communication with a first inlet, a second inlet, and an outlet, the reaction volume including reaction channels to direct a flow of liquids within the first plasma reactor;
a first electrode positioned adjacent at least a portion of a first side of the reaction volume; and
a second electrode positioned adjacent at least a portion of the second side of the reaction volume;
providing an electrical field generator electrically connected to the first electrode of the first plasma reactor and to the second electrode of the first plasma reactor, and operating the electrical field generator to generate an electrical field across at least a portion of the reaction volume of the first plasma reactor;
feeding a first stream containing a first chemical reactant in a gaseous state through the first inlet of the first plasma reactor into the reaction volume such that at least a portion of the first stream contacts at least one of the first electrode and the second electrode and generates a non-thermal plasma within the reaction volume of the first plasma reactor;
feeding a second stream containing a second chemical reactant in a liquid state into the reaction volume through the second inlet of the first plasma reactor;
controlling properties of the non-thermal plasma through adjustment of a waveform, pulse rate, amplitude, or voltage of the electrical field generated by the electrical field generator; and
collecting a product stream containing the chemical product from the outlet of the first plasma reactor.

2. The method of claim 1, wherein the reaction channels include at least one of microfluidic channels and millifluidic channels.

3. The method of claim 2, wherein the reaction channels are shaped to establish microfluidic flow of the first chemical reactant and the second chemical reactant.

4. The method of claim 1, wherein the first chemical reactant is methane.

5. The method of claim 1, wherein the second chemical reactant is an aryl heteroatom; an aryl amine, a di-aryl compound, an alkane, an alkene, an aryl, or an amine, polymers, an organometallic complex, a fine chemical, or a pharmaceutical precursor.

6. The method of claim 1, wherein the second stream also contains a catalyst.

7. The method of claim 6, wherein the catalyst comprises an organometallic catalyst or a transition metal complex.

8. The method of claim 6, wherein the catalyst includes at least one of cobalt, nickel, palladium, copper, nickel, platinum, titanium, titanium dioxide, rubidium, rhodium, or iridium.

9. The method of claim 8, further applying a machine learning module to data collected during operation of the first plasma reactor and changing at least one of a first stream flow rate, a second stream flow rate, the first chemical reactant, the second chemical reactant, the catalyst in the second stream, and the waveform, pulse rate, amplitude or voltage provided by the electrical field generator based on the machine learning module.

10. The method of claim 9, wherein the data collected during operation of the first plasma reactor includes one or more of optical data, dynamic light scattering (DLS) data, optical emission spectroscopy (OES) data, UV-visible optical absorption spectroscopy (OAS) data, infrared (IR) data, infrared photonic data, infrared thermography data, temperature data, mass spectrometry (MS) data, and nuclear magnetic resonance (NMR) data.

11. The method of claim 1, further comprising:
feeding the collected product stream into a second plasma reactor second inlet, wherein the second plasma reactor includes:
a second plasma reactor reaction volume in liquid communication with a second plasma reactor first inlet, the second plasma reactor second inlet, and a second plasma reactor outlet, the second plasma reactor reaction volume including second plasma reactor reaction channels to direct the flow of liquids within the second plasma reactor;
a second plasma reactor first electrode positioned adjacent at least a portion of a first side of the second plasma reactor reaction volume; and
a second plasma reactor second electrode position adjacent at least a portion of a second side of the second plasma reactor reaction volume;
providing the electrical field generator electrically connected to the first electrode of the second plasma reactor and to the second electrode of the second plasma reactor, and operating the electrical field generator to generate the electrical field across at least a portion of the reaction volume of the second plasma reactor;
feeding a third stream containing a third chemical reactant in a gaseous state through the first inlet of the second plasma reactor into the reaction volume such that at least a portion of the first stream contacts at least one of the first electrode and the second electrode of the second plasma reactor and generates a plasma within the reaction volume of the second plasma reactor; and
collecting a second product stream containing a second chemical product from the outlet of the second plasma reactor.

12. The method of claim 1, further comprising linking one or more additional plasma reactors in series with the first plasma reactor and with a final plasma reactor, such that at least one of the one or more additional plasma reactors receives as an input at least a portion of the product stream from the first plasma reactor and the final plasma reactor receives as an input at least a portion of a product stream from at least one of the one or more additional plasma reactors.

13. The method of claim 1, further comprising linking one or more additional plasma reactors in parallel with the first plasma reactor.

14. The method of claim 13, further comprising operating one or more additional plasma reactors in parallel with the first plasma reactor and applying a machine learning module to data collected during operation of at least one of the first plasma reactor and the one or more additional plasma reactors, and changing an operating parameter of at least one of the first plasma reactor and the one or more additional plasma reactors based on the machine learning module.

15. The method of claim 1, wherein the reaction channels comprise an upper wall at least partially formed of a first material and a lower wall at least partially formed a second material, wherein the first material is selected from a metal, a dielectric, a semiconductor, a conductor, or a combination, or a laminate of any two or more thereof.

16. The method of claim 15, wherein the reaction channels comprise at least one transparent side and the method further comprises collecting optical data or infrared data through at least one of the first material and the second material.

17. A method of hydroalkylation of a chemical reactant, the method comprising:
providing a liquid phase comprising an organometallic catalyst and the chemical reactant;
exposing a hydrocarbon to an electric field to generate a low temperature alkyl plasma; and
interfacing the low temperature alkyl plasma with the liquid phase.

18. The method of claim 17, wherein the liquid phase and the hydrocarbon are fed through a reaction channel having microchannels and the electric field is applied across the microchannels.

19. The method of claim 18, wherein the reaction channel comprises an upper wall at least partially formed of a first material and a lower wall at least partially formed of a second material;
wherein the reaction channel comprises at least one transparent side; and
wherein the method further comprises collecting optical data or infrared data through at least one of the first material and the second material.

20. A method of determining a chemical reaction coefficient for a plasma-liquid reaction system, the method comprising:
feeding a first stream containing a first chemical reactant in a gaseous state at a gaseous volumetric feed rate to a reaction volume of a plasma reactor;
feeding a second stream containing a second chemical reactant in a liquid state at a liquid volumetric feed rate into the reaction volume;
providing an electrical field across at least a portion of the reaction volume to generate a non-thermal plasma within the reaction volume of the plasma reactor;
determining a liquid hold up (epsilon) according to the gaseous volumetric feed rate and the liquid volumetric feed rate;
adjusting at least one of the gaseous volumetric feed rate and the liquid volumetric feed rate to determine an optimum epsilon value that corresponds to one of a plasma ignition event or a plasma extinction event, wherein the plasma ignition event or the plasma extinction event is determined by infrared thermography;
determining a mass transfer coefficient according to the optimum epsilon value; and
determining the chemical reaction coefficient according to the mass transfer coefficient.
